(19) United States
(12) Patent Application Publication
(10) Pub. No.: US 2025/0132257 A1
(43) Pub. Date: Apr. 24, 2025

(54) SEMICONDUCTOR DEVICE

(71) Applicant: Samsung Electronics Co., Ltd., Suwon-si (KR)

(72) Inventors: Hyo Jin KIM, Suwon-si (KR); Dong Hoon HWANG, Suwon-si (KR); Min Chan GWAK, Suwon-si (KR)

(73) Assignee: Samsung Electronics Co., Ltd., Suwon-si (KR)

(21) Appl. No.: 18/650,306

(22) Filed: Apr. 30, 2024

(30) Foreign Application Priority Data
Oct. 24, 2023 (KR) 10-2023-0142559

(51) Int. Cl. H01L 23/535; H01L 23/528; H01L 23/532; H01L 29/06; H01L 29/417; H01L 29/423; H01L 29/775

(52) U.S. Cl. CPC H01L 23/535; H01L 23/5283; H01L 23/53252; H01L 23/53257; H10D 30/43; H10D 30/6729; H10D 30/6735; H10D 62/121

(57) ABSTRACT

A semiconductor device may include a via pattern connected to a conductive pattern on a substrate, the via pattern including a lower via pattern and an upper via pattern stacked on the lower via pattern, and a wiring line connected to the upper via pattern and extending in a second direction. The wiring line may include a same metal as the upper via pattern. A bottom width of the wiring line may be greater than a top width of the wiring line. a widths of an upper face of the lower via pattern may be equal to width of the bottom face of the upper via pattern.

This application claims priority from Korean Patent Application No. 10-2023-0142559 filed on Oct. 24, 2023 in the Korean Intellectual Property Office and all the benefits accruing therefrom under 35 U.S.C. 119, the entire contents of which are herein incorporated by reference.

### BACKGROUND

### Technical Field

The present disclosure relates to a semiconductor device.

### Description of the Related Art

As one of scaling technologies for increasing density of a semiconductor device, a multi gate transistor, in which a multi-channel active pattern (or a silicon body) having a fin or nanowire shape is formed on a substrate and a gate is formed on a surface of the multi-channel active pattern, has been proposed.

Since such a multi gate transistor utilizes a three-dimensional channel, scaling may be easily performed. Further, even if a gate length of the multi gate transistor is not increased, the current control capability may be improved. Furthermore, a SCE (short channel effect), in which potential of a channel region is influenced by a drain voltage, may be effectively limited and/or suppressed.

### SUMMARY

Aspects of the present disclosure provide a semiconductor device that may improve element performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, a semiconductor device may include a conductive pattern on a substrate; a via pattern connected to the conductive pattern, the via pattern including a lower via pattern and an upper via pattern, the lower via pattern and the upper via pattern being stacked in a first direction, an upper face of the lower via pattern being in contact with a bottom face of the upper via pattern; and a wiring line on the via pattern and extending in a second direction. A metal in the wiring line may be the same as a metal in the upper via pattern. A bottom face of the wiring line and an upper face of the wiring layer may be opposite each other in the first direction. The bottom face of the wiring line may be connected to the upper via pattern. A width of the bottom face of the wiring line in a third direction may be greater than a width of the upper face of the wiring line in the third direction. A width of an upper face of the lower via pattern in the second direction may be equal to a width of a bottom face of the upper via pattern in the second direction. A width of the upper face of the lower via pattern in the third direction may be equal to a width of the bottom face of the upper via pattern in the third direction.

According to an embodiment of the present disclosure, a semiconductor device may include a conductive pattern on a substrate; an interlayer insulating film on the conductive pattern and including a via hole; a lower via pattern connected to the conductive pattern and filling a part of the via hole; and a wiring line pattern filling a remainder of the via hole. The wiring line pattern may be in contact with an upper face of the interlayer insulating film. The wiring line pattern may include an upper via pattern and a wiring extension line. The wiring line pattern may be in the via hole and in contact with an entire upper face of the lower via pattern. The wiring extension line may extend in a first direction along the upper face of the interlayer insulating film. The upper via pattern may include an upper via filling film and an upper via barrier film extending along a side wall of the upper via filling film. The wiring extension line and the upper via filling film may have an integral structure. A width of the wiring extension line in the second direction may decrease as the wiring extension line goes away from the lower via pattern.

According to an embodiment of the present disclosure, a semiconductor device may include a gate electrode on a substrate; a source/drain pattern on a side of the gate electrode; a source/drain contact on the source/drain pattern and connected to the source/drain pattern; a via pattern connected to the source/drain contact, the via pattern including a lower via pattern and an upper via pattern, which are stacked in a first direction, and an entire upper face of the lower via pattern being in contact with the upper via pattern; a gate contact connected to the gate electrode, the gate contact including a lower gate contact and an upper gate contact, which are stacked in the first direction, and an entire upper face of the lower gate contact being in contact with the upper gate contact; a first wiring extension line on the via pattern and extending in a second direction; and a second wiring extension line on the gate contact. The upper via pattern may include an upper via filling film and an upper via barrier film. The upper via filling may be directly connected to the first wiring extension line, and the upper via barrier film may extend along a side wall of the upper via filling film. The upper gate contact may include an upper gate contact filling film and an upper gate contact barrier film. The upper gate contact film may be directly connected to the second wiring extension line. The upper gate contact barrier film may extend along a side wall of the upper gate contact filling film. A width of the first wiring extension line in a third direction may decrease as the first wiring extension line goes away from the source/drain contact. A width of the second wiring extension line in the third direction may decrease as the second wiring extension line goes away from the gate electrode. The first wiring extension line, the second wiring extension line, the upper via filling film, and the upper gate contact filling film each may include ruthenium (Ru).

### BRIEF DESCRIPTION OF DRAWINGS

FIG. 1 is an example layout diagram for explaining a semiconductor device according to some embodiments.

FIG. 2 is a cross-sectional view taken along line A-A of FIG. 1.

FIG. 3 is a cross-sectional view taken along line B-B of FIG. 1.

FIG. 4 is a cross-sectional view taken along line C-C of FIG. 1.

FIG. 5 is a cross-sectional view taken along line D-D of FIG. 1.

FIG. 6 is an enlarged view of a portion P of FIG. 2.

FIG. 7 is an enlarged view of a portion Q of FIG. 3.

FIG. 8 is an enlarged view of a portion R of FIG. 4.

FIG. 9 is an enlarged view of a portion S of FIG. 5.

FIGS. 10 to 13 are diagrams for explaining a semiconductor device according to some embodiments, respectively.

FIGS. 14 to 16 are diagrams for explaining a semiconductor device according to some embodiments.

FIGS. 17 to 20 are diagrams for explaining a semiconductor device according to some embodiments.

FIGS. 21 and 22 are diagrams for explaining a semiconductor device according to some embodiments, respectively.

FIG. 23 is a diagram for explaining a semiconductor device according to some embodiments.

FIGS. 24 and 25 are diagrams for explaining the semiconductor device according to some embodiments.

FIG. 26 is a diagram for explaining a semiconductor device according to some embodiments.

FIGS. 27 to 29 are diagrams for explaining a semiconductor device according to some embodiments.

FIGS. 30 to 37 are intermediate stage diagrams for explaining a method for fabricating a semiconductor device according to some embodiments.

### DETAILED DESCRIPTION

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

A semiconductor device according to some embodiments may include a tunneling transistor (tunneling FET) or a two-dimensional material-based transistor (2D material-based FET) and a heterostructure thereof. Additionally, the semiconductor device according to some embodiments may include a bipolar junction transistor, a laterally diffused metal oxide semiconductor (LDMOS), or the like.

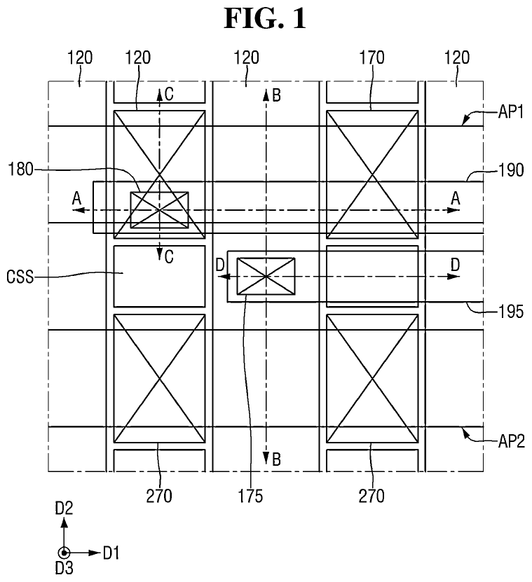

The semiconductor device according to some embodiments will be described with reference to FIGS. 1 to 9.

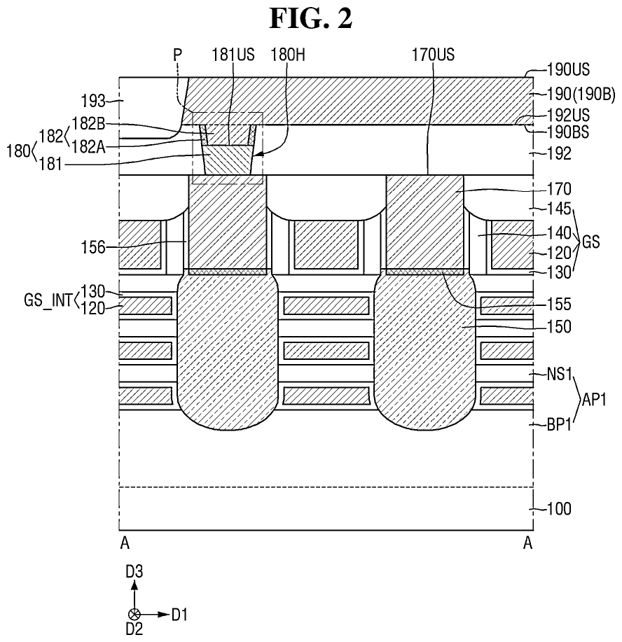

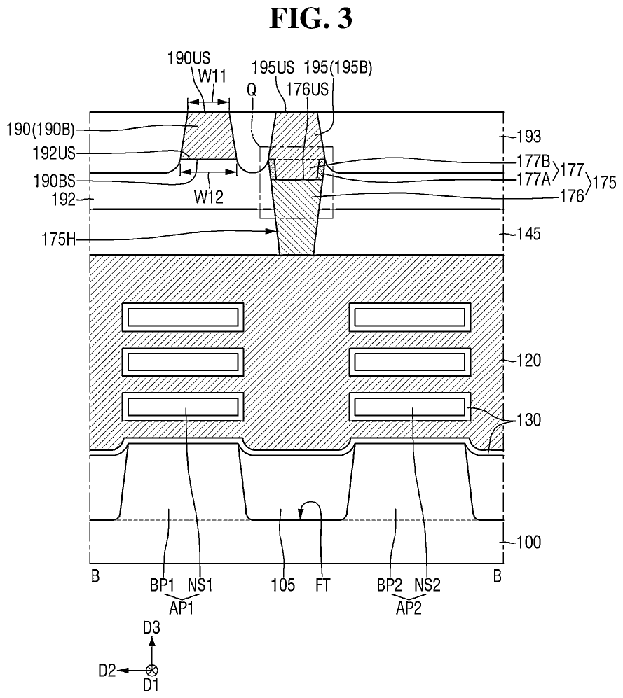

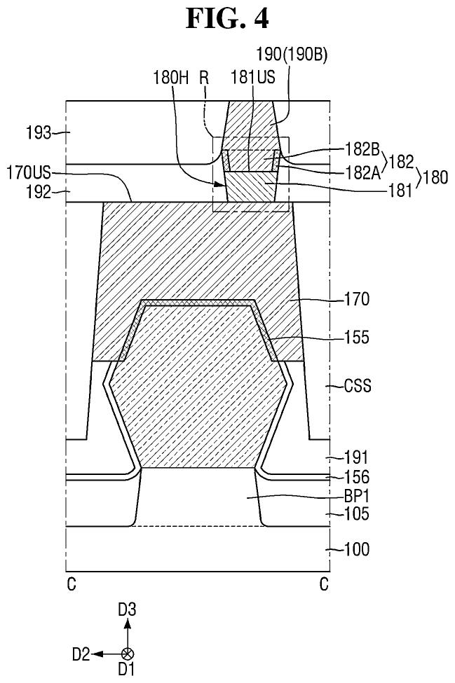

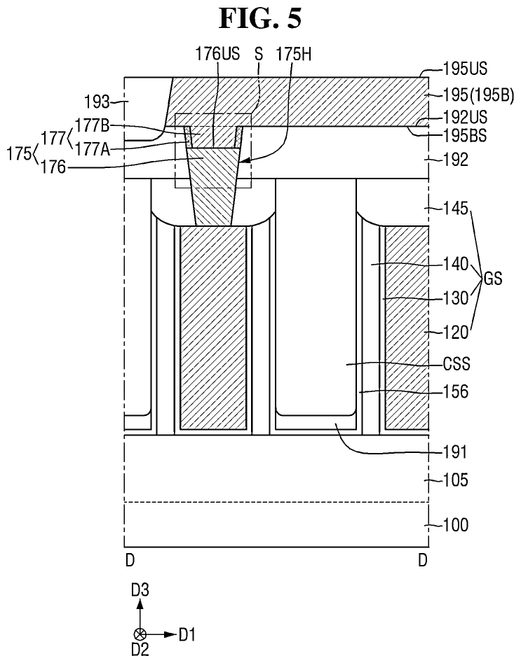

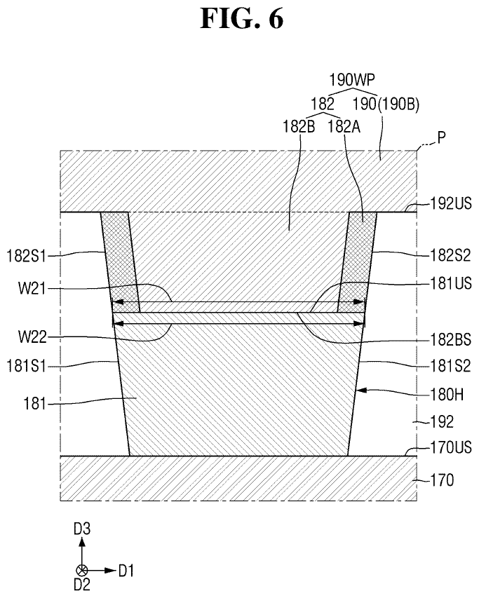

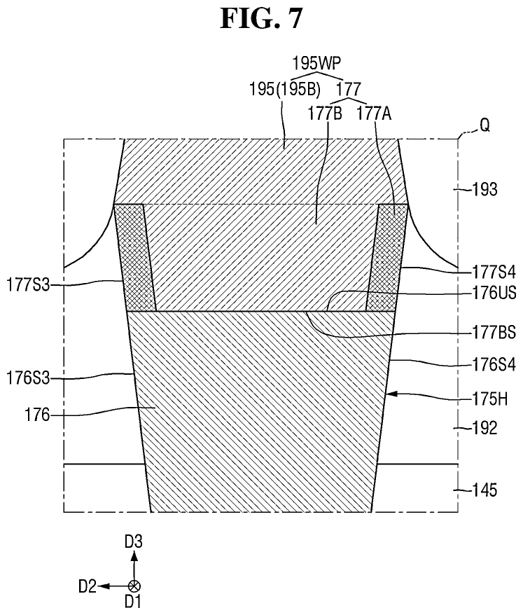

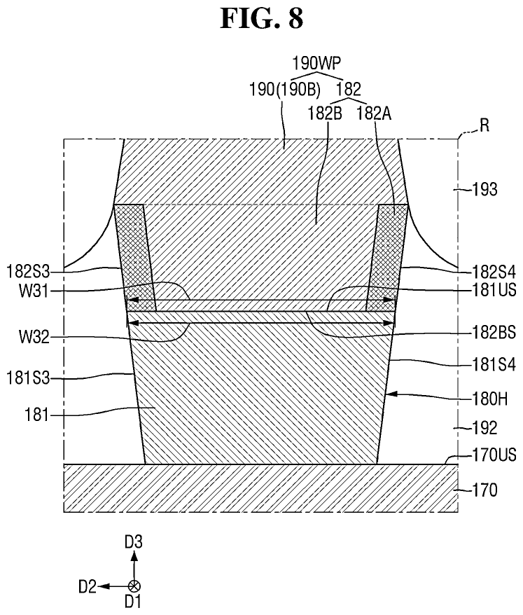

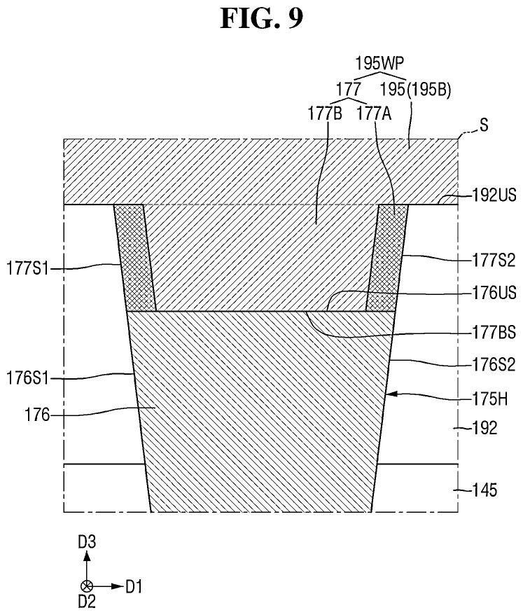

FIG. 1 is an example layout diagram for explaining a semiconductor device according to some embodiments. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1. FIG. 5 is a cross-sectional view taken along line D-D of FIG. 1. FIG. 6 is an enlarged view of a portion P of FIG. 2. FIG. 7 is an enlarged view of a portion Q of FIG. 3. FIG. 8 is an enlarged view of a portion R of FIG. 4. FIG. 9 is an enlarged view of a portion S of FIG. 5.

Referring to FIGS. 1 to 9, the semiconductor device according to some embodiments may include a first active pattern AP1, a second active pattern AP2, a plurality of first gate electrodes 120, a first source/drain pattern 150, a first source/drain contact 170, a second source/drain contact 270, a first gate contact 175, a source/drain via pattern 180, a first wiring line 190, and a second wiring line 195.

The substrate 100 may be bulk silicon or silicon-on-insulator (SOI). In contrast, the substrate 100 may be a silicon substrate or may include other materials, for example, but not limited to, silicon germanium, SGOI (silicon germanium on insulator), indium antimonide, lead tellurium compounds, indium arsenide, indium phosphide, gallium arsenide or gallium antimonide.

The first active pattern AP1 and the second active pattern AP2 may be disposed on the substrate 100, respectively. The first active pattern AP1 and the second active pattern AP2 may each extend long in a first direction D1.

The first active pattern AP1 and the second active pattern AP2 may be placed to be spaced apart from each other in a second direction D2. The first active pattern AP1 and the second active pattern AP2 may be adjacent to each other in the second direction D2.

As an example, one of the first active pattern AP1 and the second active pattern AP2 may be a region in which a p-type transistor is formed, and the other may be a region in which an n-type transistor is formed. As another example, the first active pattern AP1 and the second active pattern AP2 may be regions in which the p-type transistor is formed. As yet another example, the first active pattern AP1 and the second active pattern AP2 may be regions in which the n-type transistor is formed.

Each of the first active pattern AP1 and the second active pattern AP2 may be a multi-channel active pattern. For example, the first active pattern AP1 may include a first lower pattern BP1 and a plurality of first sheet patterns NS1. The second active pattern AP2 may include a second lower pattern BP2 and a plurality of second sheet patterns NS2. In the semiconductor device according to some embodiments, each of the first active pattern AP1 and the second active pattern AP2 may be an active pattern including nanosheet or nanowire.

Each of the first lower pattern BP1 and the second lower pattern BP2 may protrude from the substrate 100. Each of the first lower pattern BP1 and the second lower pattern BP2 may have a fin-like pattern shape.

The first lower pattern BP1 and the second lower pattern BP2 may each extend long in the first direction D1. The first lower pattern BP1 may be spaced apart from the second lower pattern BP2 in the second direction D2. The first lower pattern BP1 and the second lower pattern BP2 may be separated by a fin trench FT extending in the first direction D1. For example, a bottom face of the fin trench FT may be an upper face of the substrate 100.

The first lower pattern BP1 and the second lower pattern BP2 each include side walls extending in the first direction D1. The side walls of the first lower pattern BP1 and the side walls of the second lower pattern BP2 may be defined by the fin trench FT.

The plurality of first sheet patterns NS1 may be disposed on the first lower pattern BP1. The plurality of first sheet patterns NS1 may be spaced apart from the upper face of the first lower pattern BP1 in a third direction D3.

The plurality of second sheet patterns NS2 may be disposed on the second lower pattern BP2. The plurality of second sheet patterns NS2 may be spaced apart from the upper face of the second lower pattern BP2 in the third direction D3.

Here, the first direction D1 may intersect the second direction D2 and the third direction D3. Further, the second direction D2 may intersect the third direction D3. The third direction D3 may be a thickness direction of the substrate 100.

The first sheet pattern NS1 and the second sheet pattern NS2 may each include an upper face and a bottom face opposite to each other in the third direction D3. The bottom face of the first sheet pattern NS1 and the bottom face of the second sheet pattern NS2 may look at the substrate 100. Although three first sheet patterns NS1 and three second sheet patterns NS2 are shown as being disposed in the third direction D3, this is only for convenience of explanation, and the embodiment is not limited thereto.

Each of the first lower pattern BP1 and the second lower pattern BP2 may be formed by etching a part of the substrate 100, or may include an epitaxial layer grown from the substrate 100. Each of the first lower pattern BP1 and the second lower pattern BP2 may include silicon or germanium, which is an elemental semiconductor material. Further, each of the first lower pattern BP1 and the second lower pattern BP2 may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

Each of the first sheet pattern NS1 and the second sheet pattern NS2 may include one of silicon or germanium which is an elemental semiconductor material, a group IV-IV compound semiconductor, or a group III-V compound semiconductor. A width of the first sheet pattern NS1 in the second direction D2 may increase or decrease in proportion to a width of the first lower pattern BP1 in the second direction D2. A width of the second sheet pattern NS2 in the second direction D2 may increase or decrease in proportion to a width of the second lower pattern BP2 in the second direction D2.

Taking the first sheet pattern NS1 as an example, although the widths in the second direction D2 of each of the first sheet patterns NS1 disposed on the first lower pattern BP1 are shown as being the same, the embodiment is not limited thereto.

A field insulating film 105 is disposed on the substrate 100. The field insulating film 105 may fill at least a part of the fin trench FT that separates the first lower pattern BP1 and the second lower pattern BP2.

The field insulating film 105 may be disposed on the substrate 100 between the first lower pattern BP1 and the second lower pattern BP2. As an example, the field insulating film 105 may cover entire side walls of the first lower pattern BP1 and entire side walls of the second lower pattern BP2.

Unlike the shown example, as another example, the field insulating film 105 may cover a part of the side wall of the first lower pattern BP1 and/or a part of the side wall of the second lower pattern BP2. For example, a part of the first lower pattern BP1 and/or a part of the second lower pattern BP2 may protrude beyond the upper face of the field insulating film 105 in the third direction D3.

The field insulating film 105 does not cover the upper face of the first lower pattern BP1 and the upper face of the second lower pattern BP2. On the basis of the upper face of the substrate 100, each of the first sheet patterns NS1 and each of the second sheet patterns NS2 are disposed to be higher than the upper face of the field insulating film 105.

Although the upper face of the field insulating film 105 is shown to have a concave shape, this is only for convenience of explanation, and the embodiment is not limited thereto. The field insulating film 105 may include, for example, an oxide film, a nitride film, an oxynitride film or a combination thereof. Although the field insulating film 105 is shown as being a single film, this is only for convenience of explanation, and the embodiment is not limited thereto.

A plurality of gate structures GS may be disposed on the substrate 100. Each gate structure GS may extend in the second direction D2. The gate structures GS may be spaced apart from each other in the first direction D1. The gate structures GS may be adjacent to each other in the first direction D1.

The gate structure GS may be disposed on the first active pattern AP1 and the second active pattern AP2. The gate structure GS may intersect the first active pattern AP1 and the second active pattern AP2.

The gate structure GS may intersect the first lower pattern BP1 and the second lower pattern BP2. The gate structure GS may surround each first sheet pattern NS1. The gate structure GS may surround each second sheet pattern NS2.

Although the gate structure GS is shown as being disposed over the first active pattern AP1 and the second active pattern AP2, this is only for convenience of explanation, and the embodiment is not limited thereto. That is, although it is not shown, a part of the gate structure GS may be separated into two portions by a gate separation structure disposed on the field insulating film 105, and may be disposed on the first active pattern AP1 and the second active pattern AP2.

The gate structure GS may include, for example, a first gate electrode 120, a first gate insulating film 130, a first gate spacer 140, and a gate capping pattern 145.

The gate structure GS may include a plurality of inner gate structures GS_INT disposed between the first sheet patterns NS1 adjacent to each other in the third direction D3, and between the first lower pattern BP1 and the first sheet pattern NS1. The inner gate structure GS_INT may be disposed between the upper face of the first lower pattern BP1 and the bottom face of the first sheet pattern NS1, and between the upper face of the first sheet pattern NS1 and the bottom face of the first sheet pattern NS1 facing each other in the third direction D3.

The number of inner gate structures GS_INT may be the same as the number of first sheet patterns NS1. The inner gate structure GS_INT is in contact with the upper face of the first lower pattern BP1, the upper face of the first sheet pattern NS1, and the bottom face of the first sheet pattern NS1. In the semiconductor device according to some embodiments, the inner gate structure GS_INT may be in contact with a first source/drain pattern 150, which will be described later.

The inner gate structure GS_INT includes a first gate electrode 120 and a first gate insulating film 130 disposed between adjacent first sheet patterns NS1, and between the first lower pattern BP1 and the first sheet pattern NS1. Although it is not shown, the inner gate structure GS_INT may be disposed between the second sheet patterns NS2 adjacent to each other in the third direction D3, and between the second lower pattern BP2 and the second sheet pattern NS2.

The first gate electrode 120 may be disposed on the first lower pattern BP1 and the second lower pattern BP2. The first gate electrode 120 may intersect the first lower pattern BP1 and the second lower pattern BP2. The first gate electrode 120 may surround the first sheet pattern NS1 and the second sheet pattern NS2.

In a cross-sectional view such as FIG. 2, the upper face of the first gate electrode 120 is shown to be a concave curved face, but the embodiment is not limited thereto. It goes without saying that the upper face of the first gate electrode 120 may be a plane.

The first gate electrode 120 may include at least one of a metal, a metal alloy, a conductive metal nitride, a metal silicide, a doped semiconductor material, a conductive metal oxide, and a conductive metal oxynitride. The first gate electrode 120 may include, but not limited to, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MON), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and the conductive metal oxynitride may include, but not limited to, an oxidized form of the aforementioned materials.

The first gate insulating film 130 may extend along the upper face of the field insulating film 105, the upper face of the first lower pattern BP1, and the upper face of the second lower pattern BP2. The first gate insulating film 130 may cover the plurality of first sheet patterns NS1. The first gate insulating film 130 may cover the plurality of second sheet patterns NS2. The first gate insulating film 130 may be disposed along the periphery of the first sheet pattern NS1 and along the periphery of the second sheet pattern NS2. The first gate electrode 120 is disposed on the first gate insulating film 130.

The first gate insulating film 130 is disposed between the first gate electrode 120 and the first sheet pattern NS1, and between the first gate electrode 120 and the second sheet pattern NS2. In the semiconductor device according to some embodiments, the first gate insulating film 130 included in the inner gate structure GS_INT may be in contact with a first source/drain pattern 150, which will be described below.

The first gate insulating film 130 may include silicon oxide, silicon oxynitride, silicon nitride or a high dielectric constant material having a dielectric constant higher than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the first gate insulating film 130 is shown as a single film, this example is only for convenience of explanation and is not limited thereto. The first gate insulating film 130 may include a plurality of films. The first gate insulating film 130 may include an interfacial layer and a high dielectric constant insulating film placed between the first active pattern AP1 and the first gate electrode 120, and between the second active pattern AP2 and the first gate electrode 120. For example, the interface film may not be formed along the profile of the upper face of field insulating film 105.

A semiconductor device according to some embodiments may include an NC (Negative Capacitance) FET that uses a negative capacitor. For example, the first gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, the first gate insulating film 130 may include one ferroelectric material film. As another example, the first gate insulating film 130 may include a plurality of ferroelectric material films spaced apart from each other. The first gate insulating film 130 may have a stacked film structure in which the plurality of ferroelectric material films and the plurality of paraelectric material films are alternately stacked.

The first gate spacer 140 may be placed on the side wall of the first gate electrode 120. The first gate spacer 140 may not be placed between the first lower pattern BP1 and the first sheet pattern NS1, and between the first sheet patterns NS1 adjacent in the third direction D3.

The first gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the first gate spacer 140 is shown to be a single film, this example is only for convenience of explanation and is not limited thereto.

A gate capping pattern 145 may be placed on an upper face of the first gate electrode 120. The upper face of the gate capping pattern 145 may be an upper face of the gate structure GS. In the cross-sectional view such as FIG. 2, the gate capping pattern 145 may cover the upper face of the first gate spacer 140. Unlike the shown example, the gate capping pattern 145 may be placed between the first gate spacers 140.

The gate capping pattern 145 may include, for example, at least one of silicon nitride (SiN), silicon oxynitride (SiON), silicon carbonitride (SiCN), silicon oxycarbonitride (SiOCN), and combinations thereof. The gate capping pattern 145 may include a material having an etching selectivity with respect to a lower interlayer insulating film 191.

A first source/drain pattern 150 may be placed on the first active pattern AP1. The first source/drain pattern 150 may be placed on the first lower pattern BP1. The first source/drain pattern 150 is connected to the first sheet pattern NS1.

The first source/drain pattern 150 may be disposed on a side face of the gate structure GS. The first source/drain pattern 150 may be disposed between the gate structures GS adjacent in the first direction D1. For example, the first source/drain patterns 150 may be disposed on both sides of the gate structure GS. Unlike the shown example, the first source/drain pattern 150 may be disposed on one side of the gate structure GS, but may not be disposed on the other side of the gate structure GS.

The first source/drain pattern 150 may be included in a source/drain of a transistor that uses the first sheet pattern NS1 as a channel region.

The first source/drain pattern 150 may be in contact with the first sheet pattern NS1 and the first lower pattern BP1. For example, the first gate insulating film 130 included in the inner gate structure GS_INT may be in contact with the first source/drain pattern 150.

Although it is not shown, the second source/drain pattern may be disposed on the second active pattern AP2. The second source/drain pattern may be connected to the second sheet pattern NS2.

The first source/drain pattern 150 may include an epitaxial pattern. The first source/drain pattern 150 includes a semiconductor material.

The first source/drain pattern 150 may include, for example, silicon or germanium which is an elemental semiconductor material. Also, the first source/drain pattern 150 may include a binary compound or a ternary compound including at least two or more of carbon (C), silicon (Si), germanium (Ge), and tin (Sn), or a compound obtained by doping these elements with a group IV element. For example, the first source/drain pattern 150 may include, but not limited to, silicon, silicon-germanium, silicon carbide, or the like.

The first source/drain pattern 150 may include impurities doped into a semiconductor material. The first source/drain pattern 150 may include a p-type dopant or an n-type dopant. The p-type dopant may include, but not limited to, at least one of boron (B) and gallium (Ga). The n-type dopant may include, but not limited to, at least one of phosphorus (P), arsenic (As), antimony (Sb), and bismuth (Bi).

Although the first source/drain pattern 150 is shown as being a single film, this is only for convenience of explanation, and the embodiment is not limited thereto.

A source/drain etching stop film 156 may extend along a side wall of the gate structure GS, an upper face of the first source/drain pattern 150, a side wall of the first source/drain pattern 150, and the upper face of the field insulating film 105.

The source/drain etching stop film 156 may not extend along the side walls of the gate capping pattern 145. Unlike the shown example, the source/drain etching stop film 156 may extend along the side walls of the gate capping pattern 145.

The source/drain etching stop film 156 may include a material having an etching selectivity with respect to the lower interlayer insulating film 191. The source/drain etching stop film 156 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof. Unlike the shown example, the source/drain etching stop film 156 may not be formed.

The lower interlayer insulating film 191 may be disposed on the substrate 100. The lower interlayer insulating film 191 may be disposed on the source/drain etching stop film 156. The lower interlayer insulating film 191 may not cover the upper face of the gate capping pattern 145. For example, the upper face of the lower interlayer insulating film 191 may be disposed on the same plane as the upper face of the gate capping pattern 145.

The lower interlayer insulating film 191 may include, for example, at least one of silicon oxide, silicon nitride, silicon oxynitride, and a low dielectric constant material. The dielectric constant of the low dielectric constant material may have a value smaller than 3.9, which is the dielectric constant of silicon oxide.

A contact separation structure CSS may be disposed in the lower interlayer insulating film 191. The contact separation structure CSS may not extend to the field insulating film 105.

The contact separation structure CSS may not separate the source/drain etching stop film 156. A part of the lower interlayer insulating film 191 may be disposed between the contact separation structure CSS and the field insulating film 105. A width of the contact separation structure CSS in the second direction D2 may increase as it goes away from the field insulating film 105.

The contact separation structure CSS may be disposed on both sides of the first source/drain pattern 150. In other words, the first source/drain pattern 150 may be disposed between the contact separation structures CSS adjacent to each other in the second direction D2. Although it is not shown, the contact separation structure CSS may be disposed on both sides of the second source/drain pattern 250.

The contact separation structure CSS includes an insulating material. The contact separation structure CSS may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), aluminum oxide (AlO), and combinations thereof. Although the contact separation structure CSS is shown as being a single film, this is only for convenience of explanation, and the embodiment is not limited thereto.

The first source/drain contact 170 is disposed on the first source/drain pattern 150. The first source/drain contact 170 is electrically connected to the first source/drain pattern 150.

The first source/drain contact 170 may be placed between the contact separation structures CSS. The first source/drain contact 170 may be in contact with the contact separation structure CSS.

The first source/drain contact 170 may be disposed on the lower interlayer insulating film 191. Although an upper face 170US of the first source/drain contact may be placed on the same plane as the upper face of the gate capping pattern 145, the embodiment is not limited thereto.

The contact silicide film 155 may be disposed between the first source/drain contact 170 and the first source/drain pattern 150.

Although the first source/drain contact 170 is shown as having a single conductive film structure, the embodiment is not limited thereto. Unlike the shown example, the first source/drain contact 170 may have a multi-conductive film structure including a barrier film and a plug film. The first source/drain contact 170 may include, for example, at least one of a metal, a conductive metal nitride, a conductive metal carbide, a conductive metal oxide, a conductive metal carbonitride, and a two-dimensional material (2D material). The contact silicide film 155 may include a metal silicide material.

The 2D material may include a 2D allotrope or a 2D compound, and may include, for example, but not limited to, at least one of graphene, boron nitride (BN), molybdenum sulfide, molybdenum selenide, tungsten sulfide, tungsten selenide, and tantalum sulfide. That is, since the above-mentioned 2D materials are only listed by way of example, the 2D materials that may be included in the semiconductor device of the present disclosure are not limited by the above-mentioned materials.

Although it is not shown, the second source/drain contact 270 may be disposed on the second active pattern AP2. The second source/drain contact 270 may be connected to the second source/drain pattern. A cross-section of the second source/drain contact 270 taken in the second direction D2 may be similar to that of FIG. 4. It goes without saying that the description of the first source/drain contact 170 is also applicable to the second source/drain contact 270.

The first gate electrode 120 and the first source/drain contact 170 described above may be a conductive pattern disposed on the substrate 100. The first gate electrode 120 and the first source/drain contact 170 may be a conductive pattern connected to the first wiring line 190 and the second wiring line 195. For example, the first source/drain contact 170 may be a first conductive pattern connected to the first wiring line 190. The first gate electrode 120 may be a second conductive pattern connected to the second wiring line 195.

A first upper interlayer insulating film 192 may be disposed on the gate capping pattern 145 and the first and second source/drain contacts 170 and 270. The first upper interlayer insulating film 192 may cover the upper face 170US of the first source/drain contact.

The first upper interlayer insulating film 192 may include, for example, at least one of silicon oxide, silicon nitride, silicon oxynitride, and a low dielectric constant material. The dielectric constant of the low dielectric constant material may have a value smaller than 3.9, which is the dielectric constant of silicon oxide.

Although it is not shown, a contact etching stop film may be disposed between the first upper interlayer insulating film 192 and the gate capping pattern 145, and between the first upper interlayer insulating film 192 and the first source/drain contact 170. The contact etching stop film may include a material having an etch selectivity with respect to the first upper interlayer insulating film 192.

The first gate contact 175 may be disposed in the first upper interlayer insulating film 192 and the gate capping pattern 145. The first gate contact 175 may penetrate the first upper interlayer insulating film 192 and the gate capping pattern 145.

The first gate contact 175 may be disposed in a gate contact hole 175H. The gate contact hole 175H extends from the upper face 192US of the first upper interlayer insulating film to the upper face of the first gate electrode 120.

The first gate contact 175 is disposed on the first gate electrode 120. The first gate contact 175 may be connected to the first gate electrode 120. Although the first gate electrode 120 is shown to be disposed between the first lower pattern BP1 and the second lower pattern BP2, the embodiment is not limited thereto.

The source/drain via pattern 180 may be disposed in the first upper interlayer insulating film 192. The source/drain via pattern 180 may penetrate the first upper interlayer insulating film 192.

The source/drain via pattern 180 may be disposed in the source/drain via hole 180H. The first upper interlayer insulating film 192 includes source/drain via holes 180H.

The source/drain via pattern 180 may be connected to the first source/drain contact 170. The source/drain via pattern 180 may be disposed on the upper face 170US of the first source/drain contact. Although it is not shown, the source/drain via pattern 180 may be disposed on the second source/drain contact 280.

The first gate contact 175 may be a first via pattern connected to the first gate electrode 120. The source/drain via pattern 180 may be a second via pattern connected to first source/drain contact 170. In other words, the first gate contact 175 and the source/drain via pattern 180 may be via patterns connected to a conductive pattern on substrate 100.

The source/drain via pattern 180 may include a lower via pattern 181 and an upper via pattern 182 stacked in the third direction D3. The lower via pattern 181 and the upper via pattern 182 may be disposed in the first upper interlayer insulating film 192. The lower via pattern 181 is disposed between the first source/drain contact 170 and the upper via pattern 182.

The lower via pattern 181 may partially fill the source/drain via hole 180H. The upper via pattern 182 may fill the remainder of the source/drain via hole 180H.

The lower via pattern 181 may include an upper face 181US that looks at the upper via pattern 182. The lower via pattern 181 may include a bottom face that is opposite to the upper face 181US of the lower via pattern in the third direction D3. The upper via pattern 182 may include a bottom face 182BS that looks at the lower via pattern 181. The bottom face 182BS of the upper via pattern looks at the first source/drain contact 170. In the semiconductor device according to some embodiments, the upper face 181US of the lower via pattern may be a plane from a cross-sectional viewpoint.

In FIGS. 2 and 6, a width W21 of the upper face 181US of the lower via pattern in the first direction D1 is the same as a width W22 of the bottom face 182BS of the upper via pattern in the first direction D1. In FIGS. 4 and 8, a width W31 of the upper face 181US of the lower via pattern in the second direction D2 is the same as a width W32 of the bottom face 182BS of the upper via pattern in the second direction D2.

The upper face 181US of the lower via pattern may be in contact with the bottom face 182BS of the upper via pattern. For example, the entire upper face 181US of the lower via pattern may be in contact with the upper via pattern 182. The entire bottom face 182BS of the upper via pattern may be in contact with the lower via pattern 181.

In the semiconductor device according to some embodiments, the lower via pattern 181 may have a single film structure. The lower via pattern 181 may be formed of a single conductive material. The lower via pattern 181 may have a single conductive film structure.

The lower via pattern 181 may include a metal. The lower via pattern 181 may include, for example, one of tungsten (W), molybdenum (Mo), and cobalt (Co). For example, when the lower via pattern 181 includes molybdenum (Mo), the lower via pattern 181 may have a single film structure formed of molybdenum. Here, the single film structure formed of molybdenum does not mean a structure formed of only molybdenum. While the lower via pattern 181 including molybdenum is being formed, various impurities may flow into the lower via pattern 181. That is, the lower via pattern 181, which is a single film structure made of molybdenum, may contain impurities contained in the molybdenum film.

The upper via pattern 182 may include an upper via barrier film 182A and an upper via filling film 182B. For example, the upper via pattern 182 may be a multi-film structure including conductive materials different from each other.

The upper via barrier film 182A may extend along the side wall of the upper via filling film 182B. The upper via barrier film 182A may not extend along the bottom face of the upper via filling film 182B.

The bottom face 182BS of the upper via pattern may be defined by the upper via barrier film 182A and the upper via filling film 182B. For example, the upper via barrier film 182A and the upper via filling film 182B may be in contact with the upper face 181US of the lower via pattern. The upper via filling film 182B may be directly connected to the lower via pattern 181.

The upper via barrier film 182A may include, for example, at least one of a metal, a conductive metal nitride, a conductive metal carbide, a conductive metal oxide, a conductive metal carbonitride, and a two-dimensional material (2D material). For example, the upper via barrier film 182A may include, but not limited to, at least one of tantalum (Ta), tantalum nitride (TaN), titanium (Ti), titanium nitride (TiN), titanium silicon nitride (TiSiN), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and two-dimensional materials.

The upper via filling film 182B may include a metal. The upper via filling film 182B may include a metal different from that of the lower via pattern 181. For example, the upper via filling film 182B may include ruthenium (Ru).

The first gate contact 175 may include a lower gate contact 176 and an upper gate contact 177 stacked in the third direction D3. The lower gate contact 176 is disposed between the first gate electrode 120 and the upper gate contact 177. The lower gate contact 176 may partially fill the gate contact hole 175H. The upper gate contact 177 may fill the remainder of the gate contact hole 175H.

The lower gate contact 176 may be disposed in the first upper interlayer insulating film 192 and the gate capping pattern 145. The upper gate contact 177 may be disposed in the first upper interlayer insulating film 192.

The lower gate contact 176 may include an upper face 176US that looks at the upper gate contact 177. The lower gate contact 176 may include a bottom face opposite to the upper face 176US of the lower gate contact in the third direction D3. The upper gate contact 177 may include a bottom face 177BS that looks at the lower gate contact 176. The bottom face 177BS of the upper gate contact looks at the first gate electrode 120. In the semiconductor device according to some embodiments, the upper face 176US of the lower gate contact may be a plane from a cross-sectional viewpoint.

A part of the lower gate contact 176 may protrude beyond the upper face of the gate capping pattern 145. The upper face 176US of the lower gate contact is higher than the upper face of the gate capping pattern 145 on the basis of the upper face of the first gate electrode 120.

In FIGS. 3 and 7, a width of the upper face 176US of the lower gate contact in the second direction D2 is the same as a width of the bottom face 177BS of the upper gate contact in the second direction D2. In FIGS. 5 and 9, the width of the upper face 176US of the lower gate contact in the first direction D1 is the same as the width of the bottom face 177BS of the upper gate contact in the first direction D1.

The upper face 176US of the lower gate contact may be in contact with the bottom face 177BS of the upper gate contact. For example, the entire upper face 176US of the lower gate contact may be in contact with the upper gate contact 177. The entire bottom face 177BS of the upper gate contact may be in contact with the lower gate contact 176.

In the semiconductor devices according to some embodiments, the lower gate contact 176 may have a single film structure. The lower gate contact 176 may be formed of a single conductive material. The lower gate contact 176 may have a single conductive film structure.

The lower gate contact 176 may include a metal. The lower gate contact 176 may include, for example, one of tungsten (W), molybdenum (Mo), and cobalt (Co). As an example, the lower gate contact 176 may include the same metal as the lower via pattern 181. When the lower via pattern 181 includes molybdenum, the lower gate contact 176 may include molybdenum. As another example, the lower gate contact 176 may include a metal different from the lower via pattern 181.

The upper gate contact 177 may include an upper gate barrier film 177A and an upper gate filling film 177B. For example, the upper gate contact 177 may be a multi-film structure including conductive materials different from each other.

The upper gate barrier film 177A may extend along the side walls of the upper gate filling film 177B. The upper gate barrier film 177A may not extend along the bottom face of the upper gate filling film 177B.

The bottom face 177BS of the upper gate contact may be defined by the upper gate barrier film 177A and the upper gate filling film 177B. For example, the upper gate barrier film 177A and the upper gate filling film 177B may be in contact with the upper face 176US of the lower gate contact. The upper gate filling film 177B may be directly connected to the lower gate contact 176.

The upper gate barrier film 177A may include, for example, at least one of a metal, a conductive metal nitride, a conductive metal carbide, a conductive metal oxide, a conductive metal carbonitride, and a two-dimensional (2D) material. The upper gate filling film 177B may include a metal. The upper gate filling film 177B may include a metal different from the lower gate contact 181. The upper gate filling film 177B may include the same metal as the upper via filling film 182B. For example, the upper gate filling film 177B may include ruthenium (Ru).

In the following description of a slope of the side wall, the bottom face of the lower via pattern 181 and the bottom face of the lower gate contact 176 will be described as being a plane including the first direction D1 and the second direction D2. In other words, the bottom face of the lower via pattern 181 and the bottom face of the lower gate contact 176 will be described as being perpendicular to the third direction D3.

In FIGS. 2 and 6, the lower via pattern 181 may include a first side wall 181S1 and a second side wall 181S2 that are opposite to each other in the first direction D1. The upper via pattern 182 may include a first side wall 182S1 and a second side wall 182S2 that are opposite to each other in the first direction D1. The first side wall 182S1 of the upper via pattern and the second side wall 182S2 of the upper via pattern may be defined by the upper via barrier film 182A.

The first side wall 181S1 of the lower via pattern is connected to the first side wall 182S1 of the upper via pattern. The second side wall 181S2 of the lower via pattern is connected to the second side wall 182S2 of the upper via pattern.

For example, the first side wall 181S1 of the lower via pattern forms an obtuse angle with respect to the bottom face of the lower via pattern 181. The second side wall 181S2 of the lower via pattern forms an obtuse angle with respect to the bottom face of the lower via pattern 181. The first side wall 182S1 of the upper via pattern forms an obtuse angle with respect to the bottom face 182BS of the upper via pattern. The second side wall 182S2 of the upper via pattern forms an obtuse angle with respect to the bottom face 182BS of the upper via pattern.

Hereinafter, when the side wall forms an obtuse angle with respect to the bottom face, the slope of the side wall will be described as having a positive value. Alternatively, when the side wall forms an obtuse angle with respect to the bottom face, the side wall may have a positive slope value. In contrast, when the side walls form an acute angle with respect to the bottom face, the slope of the side walls will be described as having a negative value. Alternatively, when the side walls forms an acute angle with respect to the bottom face, the side walls may have negative slope values.

The slope of the first side wall 181S1 of the lower via pattern may have a positive value. The slope of the second side wall 181S2 of the lower via pattern may have a positive value. The slope of the first side wall 182S1 of the upper via pattern may have a positive value. The slope of the second side wall 182S2 of the upper via pattern may have a positive value.

A sign of the slope of the first side wall 181S1 of the lower via pattern is the same as a sign of the slope of the second side wall 181S2 of the lower via pattern. A sign of the slope of the first side wall 182S1 of the upper via pattern is the same as a sign of the slope of the second side wall 182S2 of the upper via pattern.

The sign of the slope of the first side wall 181S1 of the lower via pattern is the same as the sign of the slope of the first side wall 182S1 of the upper via pattern. The sign of the slope of the second side wall 181S2 of the lower via pattern is the same as the sign of the slope of the second side wall 182S2 of the upper via pattern.

In FIGS. 4 and 8, the lower via pattern 181 may include a third side wall 181S3 and a fourth side wall 181S4 that are opposite to each other in the second direction D2. The upper via pattern 182 may include a third side wall 182S3 and a fourth side wall 182S4 that are opposite to each other in the second direction D2. The third side wall 182S3 of the upper via pattern and the fourth side wall 182S4 of the upper via pattern may be defined by the upper via barrier film 182A.

The third side wall 181S3 of the lower via pattern is connected to the third side wall 182S3 of the upper via pattern. The fourth side wall 181S4 of the lower via pattern is connected to the fourth side wall 182S4 of the upper via pattern.

The slope of the third side wall 181S3 of the lower via pattern may have a positive value. The slope of the fourth side wall 181S4 of the lower via pattern may have a positive value. The slope of the third side wall 182S3 of the upper via pattern may have a positive value. The slope of the fourth side wall 182S4 of the upper via pattern may have a positive value.

The sign of the slope of the third side wall 181S3 of the lower via pattern is the same as the sign of the slope of the fourth side wall 181S4 of the lower via pattern. The sign of the slope of the third side wall 182S3 of the upper via pattern is the same as the sign of the slope of the fourth side wall 182S4 of the upper via pattern.

The sign of the slope of the third side wall 181S3 of the lower via pattern is the same as the sign of the slope of the third side wall 182S3 of the upper via pattern. The sign of the slope of the fourth side wall 181S4 of the lower via pattern is the same as the sign of the slope of the fourth side wall 182S4 of the upper via pattern.

In FIGS. 5 and 9, the lower gate contact 176 may include a first side wall 176S1 and a second side wall 176S2 that are opposite to each other in the first direction D1. The upper gate contact 177 may include a first side wall 177S1 and a second side wall 177S2 that are opposite to each other in the first direction D1. The first side wall 177S1 of the upper gate contact and the second side wall 177S2 of the upper gate contact may be defined by the upper gate barrier film 177A.

The first side wall 176S1 of the lower gate contact is connected to the first side wall 177S1 of the upper gate contact. The second side wall 176S2 of the lower gate contact is connected to the second side wall 177S2 of the upper gate contact.

A sign of the slope of the first side wall 176S1 of the lower gate contact is the same as a sign of the slope of the second side wall 176S2 of the lower gate contact. A sign of the slope of the first side wall 177S1 of the upper gate contact is the same as a sign of the slope of the second side wall 177S2 of the upper gate contact.

The sign of the slope of the first side wall 176S1 of the lower gate contact is the same as the sign of the slope of the first side wall 177S1 of the upper gate contact. The sign of the slope of the second side wall 176S2 of the lower gate contact is the same as the sign of the slope of the second side wall 177S2 of the upper gate contact.

In FIGS. 3 and 7, the lower gate contact 176 may include a third side wall 176S3 and a fourth side wall 176S4 that are opposite to each other in the second direction D2. The upper gate contact 177 may include a third side wall 177S3 and a fourth side wall 177S4 that are opposite to each other in the second direction D2. The third side wall 177S3 of the upper gate contact and the fourth side wall 177S4 of the upper gate contact may be defined by the upper gate barrier film 177A.

The third side wall 176S3 of the lower gate contact is connected to the third side wall 177S3 of the upper gate contact. The fourth side wall 176S4 of the lower gate contact is connected to the fourth side wall 177S4 of the upper gate contact.

A sign of the slope of the third side wall 176S3 of the lower gate contact is the same as a sign of the slope of the fourth side wall 176S4 of the lower gate contact. A sign of the slope of the third side wall 177S3 of the upper gate contact is the same as a sign of the slope of the fourth side wall 177S4 of the upper gate contact.

The sign of the slope of the third side wall 176S3 of the lower gate contact is the same as the sign of the slope of the third side wall 177S3 of the upper gate contact. The sign of the slope of the fourth side wall 176S4 of the lower gate contact is the same as the sign of the slope of the fourth side wall 177S4 of the upper gate contact.

The first wiring line 190 may be disposed on the source/drain via pattern 180. The first wiring line 190 is connected to the source/drain via pattern 180.

The second wiring line 195 may be disposed on the first gate contact 175. The second wiring line 195 is connected to the first gate contact 175.

The first wiring line 190 and the second wiring line 195 may each extend in the first direction D1. The first wiring line 190 may be spaced apart from the second wiring line 195 in the second direction D2. The first wiring line 190 and the second wiring line 195 may extend along the upper face 192US of the first upper interlayer insulating film. Each of the first wiring line 190 and the second wiring line 195 may be in contact with the upper face 192US of the first upper interlayer insulating film.

The first wiring line 190 may include an upper face 190US and a bottom face 190BS that are opposite to each other in the third direction D3. The bottom face 190BS of the first wiring line looks at the first upper interlayer insulating film 192. The bottom face 190BS of the first wiring line is in contact with the upper face 192US of the first upper interlayer insulating film. The bottom face 190BS of the first wiring line is connected to the upper via pattern 182.

The second wiring line 195 may include an upper face 195US and a bottom face 195BS that are opposite to each other in the third direction D3. The bottom face 195BS of the second wiring line looks at the first upper interlayer insulating film 192. The bottom face 195BS of the second wiring line is in contact with the upper face 192US of the first upper interlayer insulating film. The bottom face 195BS of the second wiring line is connected to the upper gate contact 177.

The first wiring line 190 will be explained as an example. A width of the first wiring line 190 in the second direction D2 may decrease as it goes away from the first upper interlayer insulating film 192. The width of the first wiring line 190 in the second direction D2 may decrease as it goes away from the lower via pattern 181. A width W12 of the bottom face 190BS of the first wiring line in the second direction D2 may be greater than a width W11 of the upper face 190US of the first wiring line in the second direction D2.

The upper face 192US of the first upper interlayer insulating film may be confirmed through the bottom face 190BS of the first wiring line and the bottom face 195BS of the second wiring line. For example, the source/drain via pattern 180 and the first wiring line 190 may be divided on the basis of the upper face 192US of the first upper interlayer insulating film. The first gate contact 175 and the second wiring line 195 may be divided on the basis of the upper face 192US of the first upper interlayer insulating film.

In the semiconductor device according to some embodiments, each of the first wiring line 190 and the second wiring line 195 may have a single film structure. Each of the first wiring line 190 and the second wiring line 195 may have a single conductive film structure.

Each of the first wiring line 190 and the second wiring line 195 may include metal. For example, each of the first wiring line 190 and the second wiring line 195 may be formed of a single metal conductive film. The first wiring line 190 and the second wiring line 195 may include ruthenium (Ru).

The first wiring line 190 may include the same material as the upper via filling film 182B. The metal included in the first wiring line 190 may be the same as the metal included in the upper via filling film 182B. The second wiring line 195 may include the same material as the upper gate filling film 177B.

The first wiring line 190 may include a first wiring extension line 190B extending in the first direction D1. The first wiring extension line 190B may include an upper face 190US of the first wiring line and a bottom face 190BS of the first wiring line. The first wiring extension line 190B may be in contact with the upper face 192US of the first upper interlayer insulating film.

The second wiring line 195 may include a second wiring extension line 195B extending in the first direction D1. The second wiring extension line 195B may include an upper face 195US of the second wiring line and a bottom face 195BS of the second wiring line. The second wiring extension line 195B may be in contact with the upper face 192US of the first upper interlayer insulating film.

The width of the first wiring extension line 190B in the second direction D2 may decrease as it goes away from the lower via pattern 181. The width of the first wiring extension line 190B in the second direction D2 may decrease as it goes away from the first source/drain contact 170. The width of the second wiring extension line 195B in the second direction D2 may decrease as it goes away from the lower gate contact 176. The width of the second wiring extension line 195B in the second direction D2 may decrease as it goes away from the first gate electrode 120.

The first wiring extension line 190B and the second wiring extension line 195B may include ruthenium (Ru). The first wiring extension line 190B and the second wiring extension line 195B may be a metal conductive film formed of ruthenium.

The first wiring extension line 190B and the upper via filling film 182B may include ruthenium. Each of the first wiring extension line 190B and the upper via filling film 182B may be formed of ruthenium. The first wiring extension line 190B may be directly connected to the upper via filling film 182B. For example, a boundary between the first wiring extension line 190B and the upper via filling film 182B may not be distinguished. The first wiring extension line 190B and the upper via filling film 182B may have an integral structure.

Each of the second wiring extension line 195B and the upper gate filling film 177B may be formed of ruthenium. The second wiring extension line 195B may be directly connected to the upper gate filling film 177B. The second wiring extension line 195B and the upper gate filling film 177B may have an integral structure.

The first wiring line pattern 190WP may be placed on the lower via pattern 181. The first wiring line pattern 190WP may include the upper via pattern 182 and the first wiring line 190.

The first wiring line pattern 190WP may fill the remainder of the source/drain via holes 180H that remains after the lower via pattern 181 is disposed. The first wiring line pattern 190WP may be in contact with the upper face 192US of the first upper interlayer insulating film.

The second wiring line pattern 195WP may be disposed on the lower gate contact 176. The second wiring line pattern 195WP may include an upper gate contact 177 and a second wiring line 195.

The second wiring line pattern 195WP may fill the remaining gate contact hole 175H that remains after the lower gate contact 176 is disposed. The second wiring line pattern 195WP may be in contact with the upper face 192US of the first upper interlayer insulating film.

Since the first wiring line 190 and the second wiring line 195 are formed through subtractive etching, it may be easy to ensure a separation distance between the first wiring line 190 and the second wiring line 195.

The source/drain via pattern 180 will be explained as an example. Side walls 181S1, 181S2, 181S3, and 181S4 of the lower via pattern 181 are covered with the first upper interlayer insulating film 192. When the lower via pattern 181 includes molybdenum, molybdenum may be easily oxidized. Furthermore, it is not easy to reduce the oxidized molybdenum.

In a state in which the first upper interlayer insulating film 192 covers the side walls of the lower via pattern 181, a manufacturing process for forming the first wiring line 190 and the second wiring line 195 is performed. That is, while the etching process for forming the first wiring line 190 and the second wiring line 195 is being performed, the lower via pattern 181 is not exposed to the etching environment. This may limit and/or prevent the lower via pattern 181 from being oxidized.

The second upper interlayer insulating film 193 may be disposed on the first upper interlayer insulating film 192. The second upper interlayer insulating film 193 may cover the side walls of the first wiring line 190.

The second upper interlayer insulating film 193 may include, for example, at least one of silicon oxide, silicon nitride, silicon oxynitride, and a low dielectric constant material. The dielectric constant of the low dielectric constant material may have a value smaller than 3.9, which is the dielectric constant of silicon oxide.

The boundary between the first upper interlayer insulating film 192 and the second upper interlayer insulating film 193 may include a recessed portion toward the substrate 100. Unlike the shown example, the boundary between the first upper interlayer insulating film 192 and the second upper interlayer insulating film 193 may not be distinguished, depending on the materials included in the first upper interlayer insulating film 192 and the second upper interlayer insulating film 193.

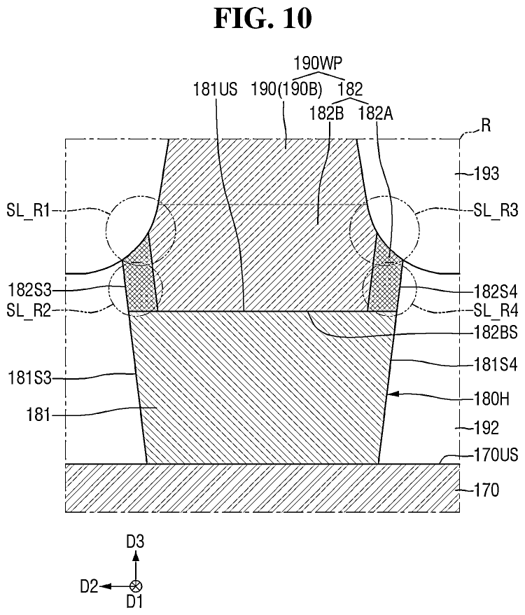

FIGS. 10 to 13 are diagrams for explaining a semiconductor device according to some embodiments, respectively. For convenience of explanation, the explanation will focus on points that are different from those explained using FIGS. 1 to 9.

For reference, FIGS. 10 to 12 are enlarged views showing a portion R of FIG. 4. Even if the enlarged view of the portion R of FIG. 5 changes like FIGS. 10 to 12, the enlarged views of the portion P of FIG. 2 and the portion S of FIG. 5 may not change. Further, the enlarged view showing the portion Q of FIG. 3 may be similar to one of FIGS. 10 to 12.

Referring to FIGS. 10 to 12, in the semiconductor device according to some embodiments, the fourth side wall 182S4 of the upper via pattern may include a third portion SL_R3 and a fourth portion SL_R4 having slope signs different from each other.

The fourth portion SL_R4 of the fourth side wall 182S4 of the upper via pattern may be disposed between the third portion SL_R3 of the third side wall 182S3 of the upper via pattern and the fourth side wall 181S4 of the lower via pattern.

The fourth portion SL_R4 of the fourth side wall 182S4 of the upper via pattern may be defined by the upper via barrier film 182A. The third portion SL_R3 of the fourth side wall 182S4 of the upper via pattern may be defined by the upper via barrier film 182A and the upper via filling film 182B.

The fourth portion SL_R4 of the fourth side wall 182S4 of the upper via pattern may have a positive slope value. The third portion SL_R3 of the fourth side wall 182S4 of the upper via pattern may have a negative slope value.

In the following description, a sign of a slope of the fourth side wall 182S4 of the upper via pattern will be described as being a sign of a slope of the third portion SL_R3 of the fourth side wall 182S4 of the upper via pattern close to the first wiring line 190. That is, the slope of the fourth side wall 182S4 of the upper via pattern may have a negative value.

Since the slope of the fourth side wall 181S4 of the lower via pattern has a positive value, the sign of the slope of the fourth side wall 182S4 of the upper via pattern may be different from the sign of the slope of the fourth side wall 181S4 of the lower via pattern.

Unlike the shown example, the fourth side wall 182S4 of the upper via pattern may not include the fourth portion SL_R4 of the third side wall 182S3 of the upper via pattern having a positive slope value.

In FIG. 10, the third side wall 182S3 of the upper via pattern may include a first portion SL_R1 and a second portion SL_R2 having slope signs different from each other. The second portion SL_R2 of the third side wall 182S3 of the upper via pattern may be disposed between the first portion SL_R1 of the third side wall 182S3 of the upper via pattern and the third side wall 181S3 of the lower via pattern.

The second portion SL_R2 of the third side wall 182S3 of the upper via pattern may be defined by the upper via barrier film 182A. The first portion SL_R1 of the third side wall 182S3 of the upper via pattern may be defined by the upper via barrier film 182A and the upper via filling film 182B.

The second portion SL_R2 of the third side wall 182S3 of the upper via pattern may have a positive slope value. The first portion SL_R1 of the third side wall 182S3 of the upper via pattern may have a negative slope value.

The slope of the third side wall 182S3 of the upper via pattern may have a negative value. Since the slope of the third side wall 181S3 of the lower via pattern has a positive value, the sign of the slope of the third side wall 182S3 of the upper via pattern may be different from the sign of the slope of the fourth side wall 181S4 of the lower via pattern. On the other hand, the sign of the slope of the third side wall 182S3 of the upper via pattern may be the same as the sign of the slope of the fourth side wall 182S4 of the upper via pattern.

Unlike the shown example, the third side wall 182S3 of the upper via pattern may not include the fourth portion SL_R4 of the third side wall 182S3 of the upper via pattern having a positive slope value.

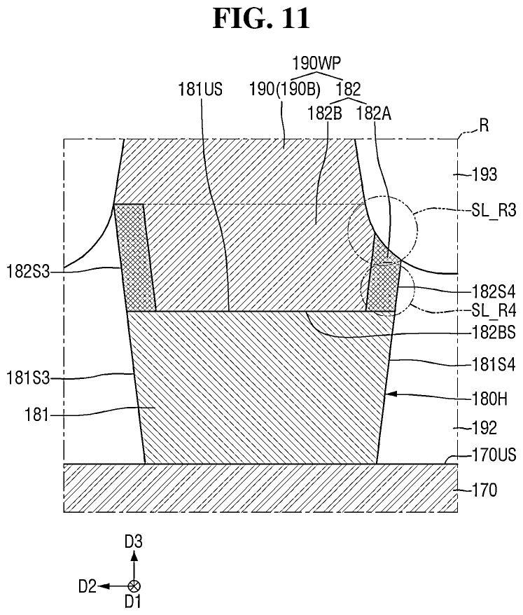

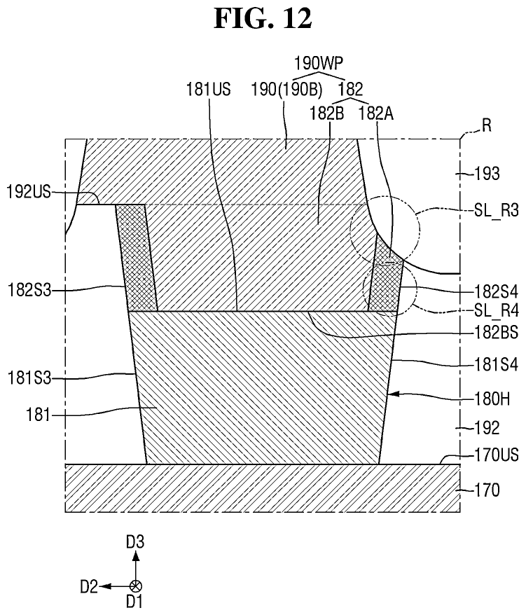

In FIGS. 11 and 12, the third side wall 182S3 of the upper via pattern may not include portions having slope signs different from each other. The slope of the third side wall 182S3 of the upper via pattern may have a positive value.

Since the fourth side wall 182S4 of the upper via pattern may have a negative slope value, the sign of the slope of the third side wall 182S3 of the upper via pattern may be different from the sign of the slope of the fourth side wall 182S4 of the upper via pattern.

In FIG. 11, the side wall of the first wiring line 190 may be directly connected to the third side wall 182S3 of the upper via pattern from the cross-sectional viewpoint.

In FIG. 12, from the cross-sectional viewpoint, the upper face 192US of the first upper interlayer insulating film may connect the side wall of the first wiring line 190 and the third side wall 182S3 of the upper via pattern.

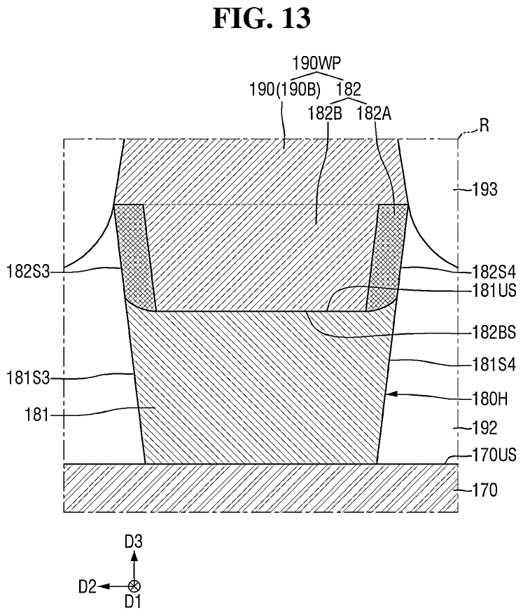

Referring to FIG. 13, in the semiconductor device according to some embodiments, the upper face 181US of the lower via pattern may include a concave curved face.

Although it is not shown, the upper face (176US of FIG. 3) of the lower gate contact may include a concave curved face.

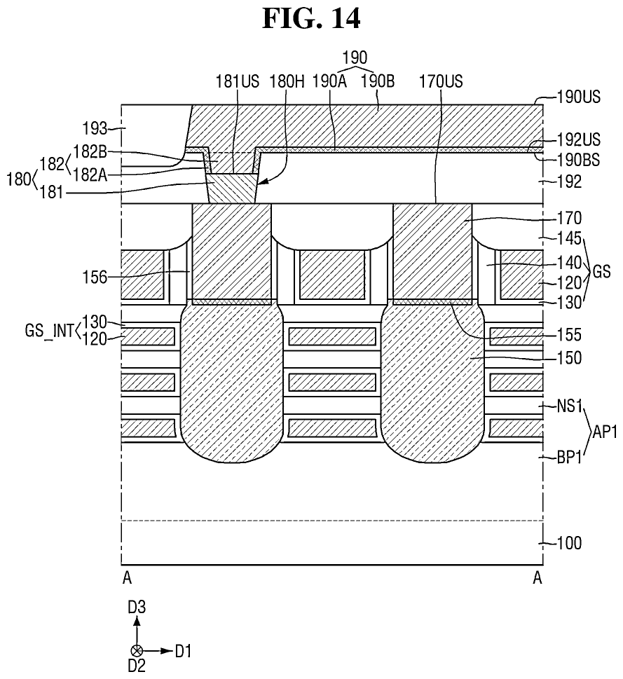

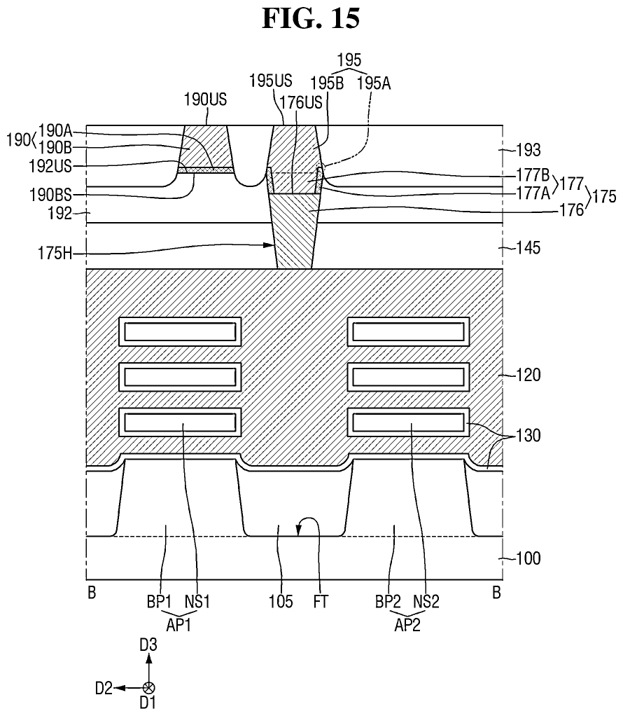

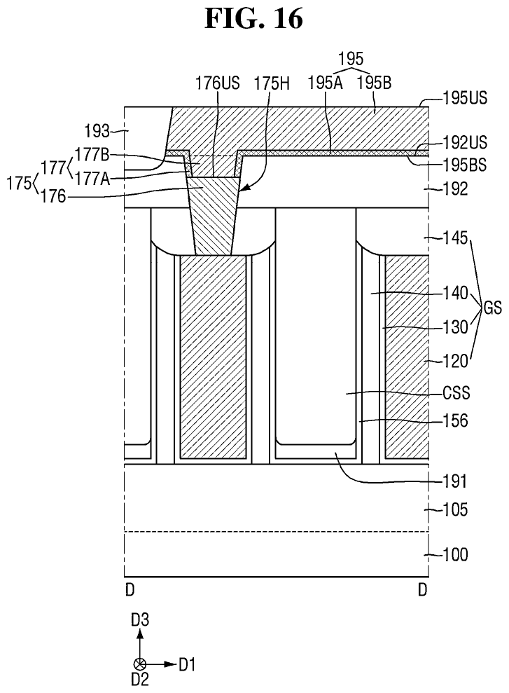

FIGS. 14 to 16 are diagrams for explaining a semiconductor device according to some embodiments. For convenience of explanation, the explanation will focus on points that are different from those explained using FIGS. 1 to 9.

Referring to FIGS. 14 to 16, in the semiconductor device according to some embodiments, the first wiring line 190 may include a first wiring barrier film 190A and a first wiring extension line 190B.

The first wiring barrier film 190A may extend along the bottom face of the first wiring extension line 190B. The first wiring extension line 190B may include an upper face 190US of the first wiring line. The first wiring barrier film 190A may include a bottom face 190BS of the first wiring line. The first wiring barrier film 190A may be in contact with the upper face 192US of the first upper interlayer insulating film.

The first wiring barrier film 190A may be directly connected to the upper via barrier film 182A. The first wiring barrier film 190A includes the same conductive material as the upper via barrier film 182A.

The second wiring line 195 may include a second wiring barrier film 195A and a second wiring extension line 195B.

The second wiring barrier film 195A may extend along the bottom face of the second wiring extension line 195B. The second wiring extension line 195B may include an upper face 195US of the second wiring line. The second wiring barrier film 195A may include a bottom face 195BS of the second wiring line. The second wiring barrier film 195A may be in contact with the upper face 192US of the first upper interlayer insulating film.

The second wiring barrier film 195A may be directly connected to the upper gate barrier film 177A. The second wiring barrier film 195A includes the same conductive material as the upper gate barrier film 177A.

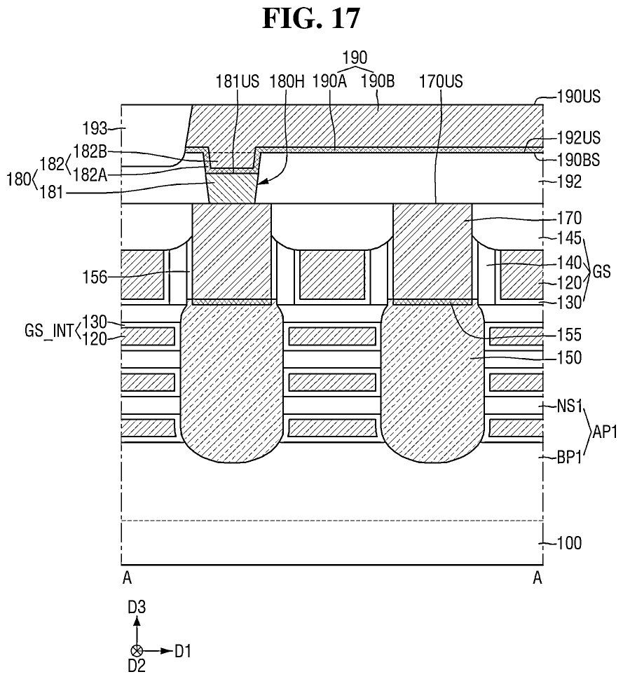

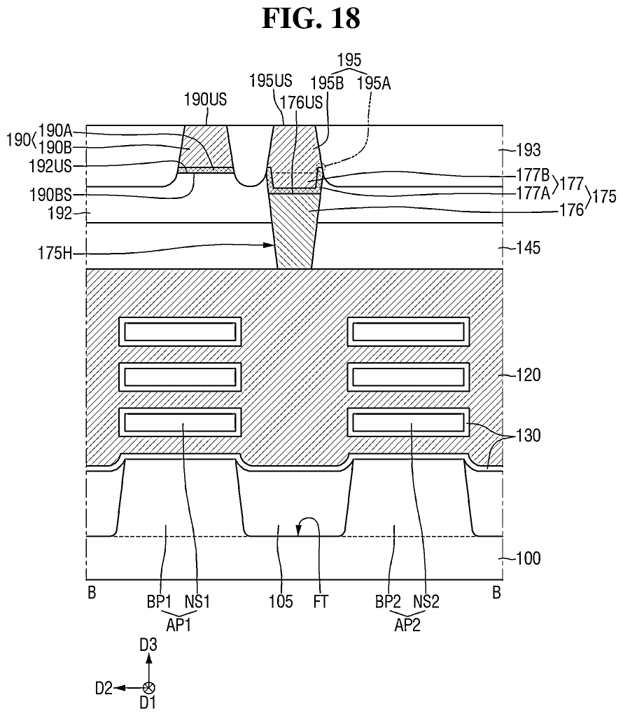

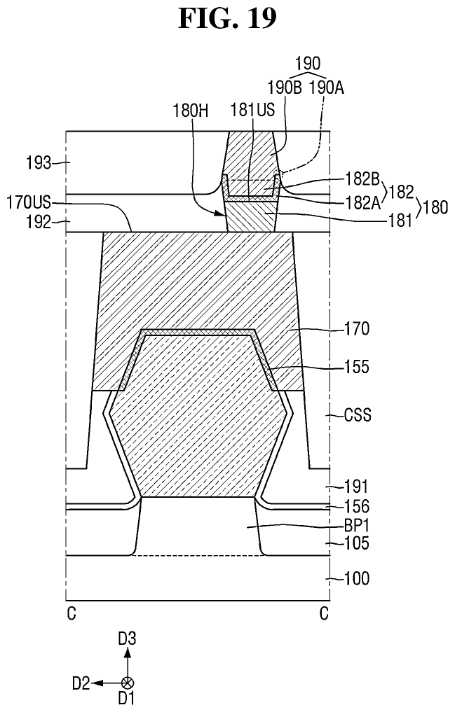

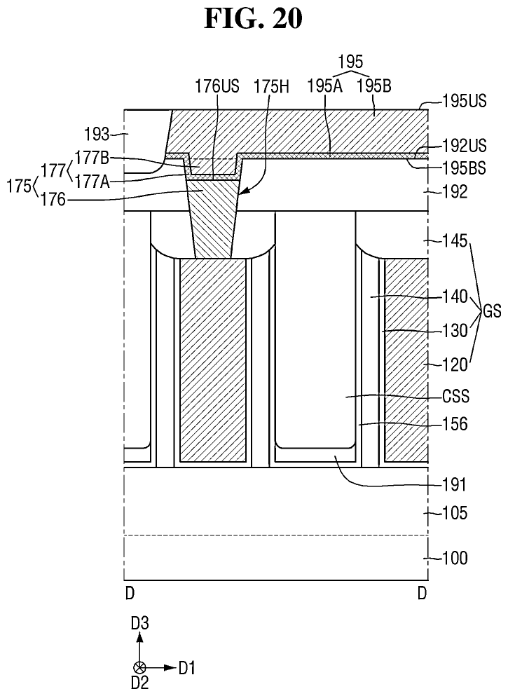

FIGS. 17 to 20 are diagrams for explaining a semiconductor device according to some embodiments. For convenience of explanation, the explanation will focus on the points that are different from those explained using FIGS. 1 to 9 and 14 to 16.

Referring to FIGS. 17 to 20, in the semiconductor device according to some embodiments, the upper via barrier film 182A may extend along the side walls of the upper via filling film 182B and the bottom face of the upper via filling film 182B.

The bottom face 182BS of the upper via pattern may be defined by the upper via barrier film 182A. The upper via filling film 182B and the lower via pattern 181 may be separated by the upper via barrier film 182A. The upper via filling film 182B is not in contact with the upper face 181US of the lower via pattern.

The upper gate barrier film 177A may extend along the side walls of the upper gate filling film 177B and the bottom face of the upper gate filling film 177B.

The bottom face 177BS of the upper gate contact may be defined by the upper gate barrier film 177A. The upper gate filling film 177B and the lower gate contact 176 may be separated by the upper gate barrier film 177A. The upper gate filling film 177B is not in contact with the upper face 176US of the lower gate contact.

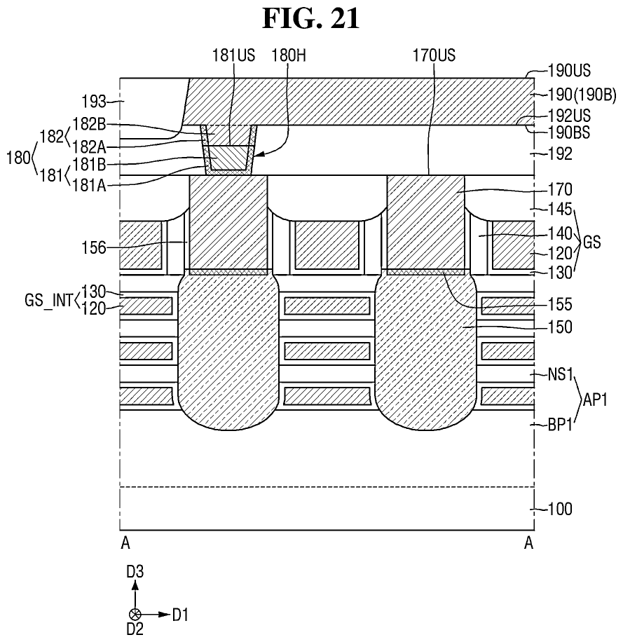

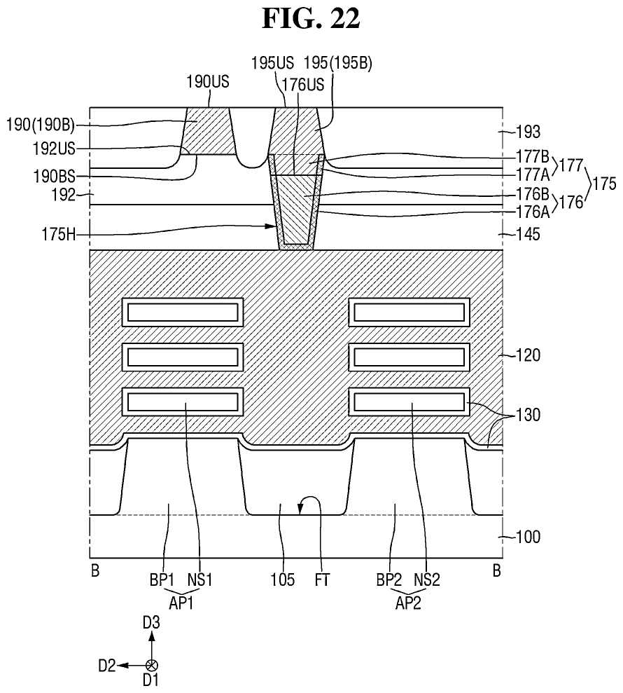

FIGS. 21 and 22 are diagrams for explaining a semiconductor device according to some embodiments, respectively. For convenience of explanation, the explanation will focus on points that are different from those explained using FIGS. 1 to 9.

Referring to FIG. 21, in the semiconductor device according to some embodiments, the lower via pattern 181 may include a lower via barrier film 181A and a lower via filling film 181B.

The lower via pattern 181 may have a multi-film structure including conductive materials different from each other. The lower via barrier film 181A may extend along the side walls of the lower via filling film 181B and the bottom face of the lower via filling film 181B. The upper face 181US of the lower via pattern may be defined by the lower via barrier film 181A and the lower via filling film 181B.

The lower via barrier film 181A may include, for example, at least one of a metal, a conductive metal nitride, a conductive metal carbide, a conductive metal oxide, a conductive metal carbonitride, and a two-dimensional material (2D material). The lower via filling film 181B may include a metal. The lower via filling film 181B may include a metal different from the upper via filling film 182B.

Referring to FIG. 22, in the semiconductor device according to some embodiments, the lower gate contact 176 may include a lower gate barrier film 176A and a lower gate filling film 176B. For example, the lower gate contact 176 may be a multi-film structure including conductive materials different from each other.

The lower gate barrier film 176A may extend along the side walls of the lower gate filling film 176B and the bottom face of the lower gate filling film 176B. The upper face 176US of the lower gate contact may be defined by the lower gate barrier film 176A and the lower gate filling film 176B.

The lower gate barrier film 176A may include, for example, at least one of a metal, a conductive metal nitride, a conductive metal carbide, a conductive metal oxide, a conductive metal carbonitride, and a two-dimensional material (2D material). The lower gate filling film 176B may include a metal. The lower gate filling film 176B may include a metal different from the upper gate filling film 177B.

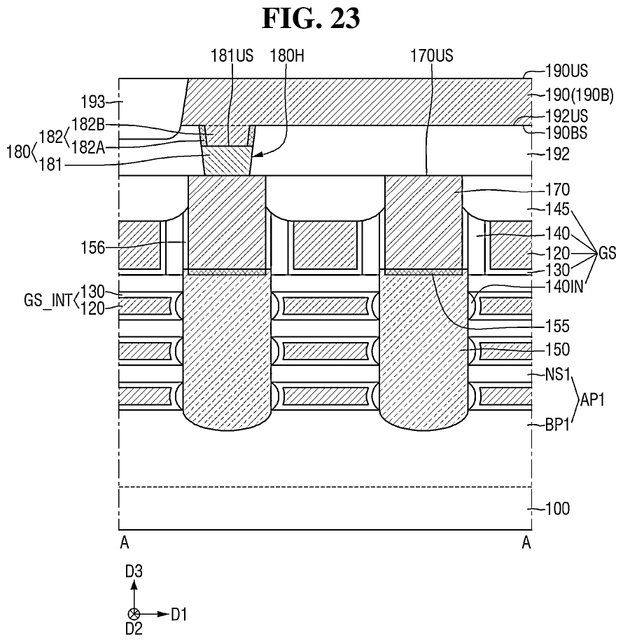

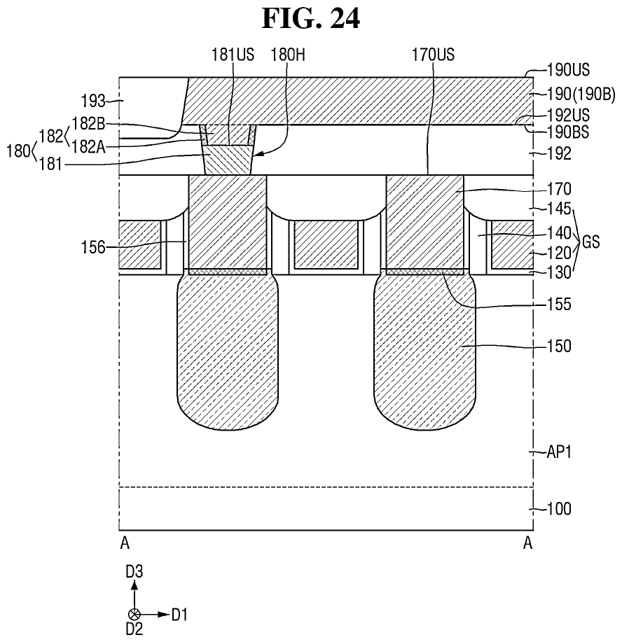

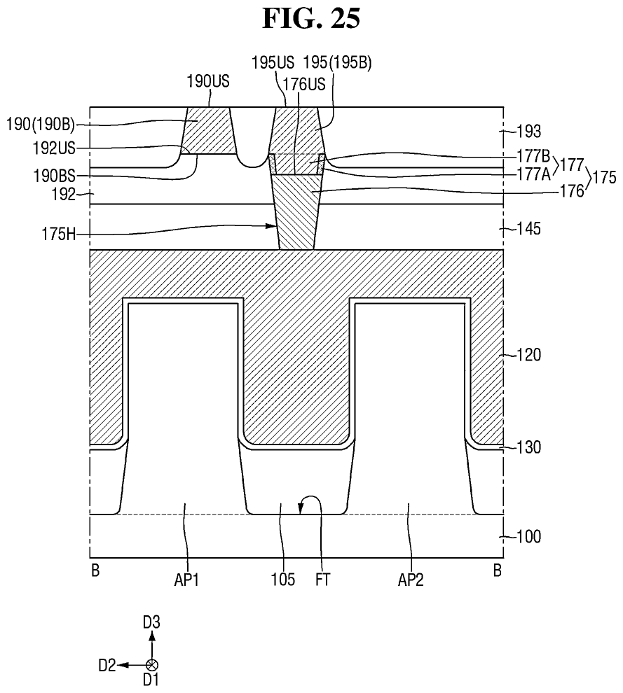

FIG. 23 is a diagram for explaining a semiconductor device according to some embodiments. FIGS. 24 and 25 are diagrams for explaining the semiconductor device according to some embodiments. For convenience of explanation, the explanation will focus on points that are different from those explained using FIGS. 1 to 9.

Referring to FIG. 23, in the semiconductor device according to some embodiments, the gate structure GS may further include a plurality of inner spacers 140IN.

The inner spacer 140IN may be disposed between the first sheet patterns NS1 adjacent to each other in the third direction D3, and between the first lower pattern BP1 and the first sheet pattern NS1. The inner spacer 140IN may be disposed between the inner gate structure GS_INT and the first source/drain pattern 150.

The inner gate structure GS_INT may not be in contact with the first source/drain pattern 150. For example, the first source/drain pattern 150 may include an n-type dopant.

Referring to FIGS. 24 and 25, in the semiconductor device according to some embodiments, the first active pattern AP1 and the second active pattern AP2 may not include sheet patterns (NS1, NS2 of FIG. 3).

No inner gate structure (GS_INT of FIG. 2) is disposed between the first source/drain patterns 150.

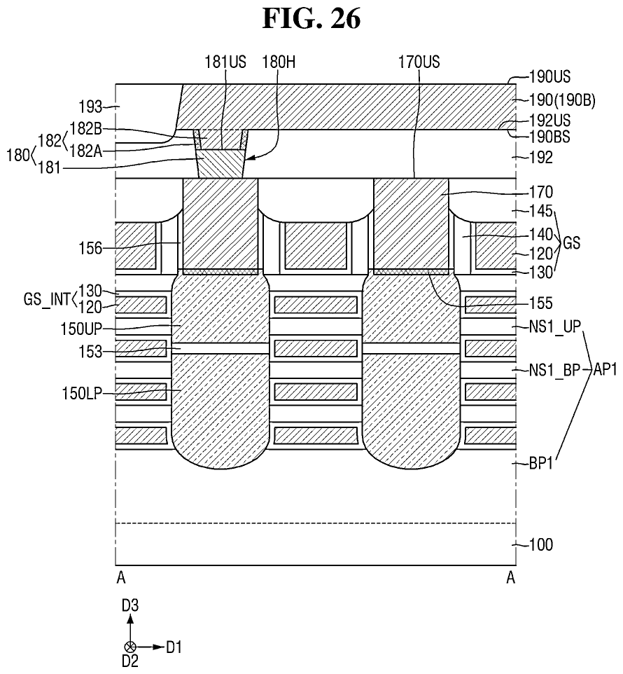

FIG. 26 is a diagram for explaining a semiconductor device according to some embodiments. For convenience of explanation, the explanation will focus on points that are different from those explained using FIGS. 1 to 9.

Referring to FIG. 26, in the semiconductor device according to some embodiments, the first active pattern AP1 may include a first lower pattern BP1, a first lower sheet pattern NS1_BP, and a first upper lower sheet pattern NS1_UP.

The first lower sheet pattern NS1_BP may be spaced apart from the first lower pattern BP1 in the third direction D3. The first upper lower sheet pattern NS1_UP may be disposed on the first lower sheet patterns NS1_BP. The first upper lower sheet pattern NS1_UP may be spaced apart from the first lower sheet pattern NS1_BP in the third direction D3.

Although each of three first lower sheet patterns NS1_BP and three first upper lower sheet patterns NS1_UP is shown as being disposed in the third direction D3, this is only for convenience of explanation, and the embodiment is not limited thereto.

The first lower sheet pattern NS1_BP and the first upper lower sheet pattern NS1_UP may each include one of silicon or germanium which is an elemental semiconductor material, a group IV-IV compound semiconductor or a group III-V compound semiconductor. The first lower sheet pattern NS1_BP and the first upper lower sheet pattern NS1_UP may include the same material or may include different materials.

As an example, one of the first lower sheet pattern NS1_BP and the first upper lower sheet pattern NS1_UP may be a channel region of a PMOS, and the other may be a channel region of an NMOS. As another example, the first lower sheet pattern NS1_BP and the first upper lower sheet pattern NS1_UP may be a channel region of the PMOS. As yet another example, the first lower sheet pattern NS1_BP and the first upper lower sheet pattern NS1_UP may be a channel region of the NMOS.

As shown in FIG. 3, the first gate insulating film 130 may surround the periphery of the first lower sheet pattern NS1_BP and the periphery of the first upper lower sheet pattern NS1_UP. As shown in FIG. 3, the first gate electrode 120 may surround the periphery of the first lower sheet pattern NS1_BP and the periphery of the first upper lower sheet pattern NS1_UP.

The first lower source/drain pattern 150_LP may be disposed on the first lower pattern BP1. The first lower source/drain pattern 150_LP may be connected to the first lower sheet pattern NS1_BP.

The first upper source/drain pattern 150_UP may be disposed on the first lower source/drain pattern 150_LP. The first upper source/drain pattern 150_UP may be connected to the first upper sheet pattern NS1_UP. The first upper source/drain pattern 150_UP is spaced apart from the first lower source/drain pattern 150_LP in the third direction D3.

For example, the first upper source/drain pattern 150_UP and the first lower source/drain pattern 150_LP may be in contact with the first gate insulating film 130. Unlike the shown example, at least one of the first upper source/drain pattern 150_UP and the first lower source/drain pattern 150_LP may not be in contact with the first gate insulating film 130.

An inserted interlayer insulating film 153 may be disposed between the first upper source/drain pattern 150_UP and the first lower source/drain pattern 150_LP.

The interlayer insulating film 153 may include an insulating material. The inserted interlayer insulating film 153 may include, for example, but not limited to, at least one of silicon oxide, silicon nitride, silicon oxynitride, silicon oxycarbide, silicon oxycarbonitride, silicon carbonitride, and a low dielectric constant material.

The first source/drain contact 170 may be connected to the first upper source/drain pattern 150_UP. Although it is not shown, the first source/drain contact 170 may be connected to the first lower source/drain pattern 150_LP.

A part of the first source/drain contact 170 may be connected to the first lower source/drain pattern 150_LP, and the remainder of the first source/drain contact 170 may be connected to the first upper source/drain pattern 150_UP.

Although it is not shown, a cross-sectional view taken along the second active pattern AP2 in the first direction D1 may be similar to FIG. 26.

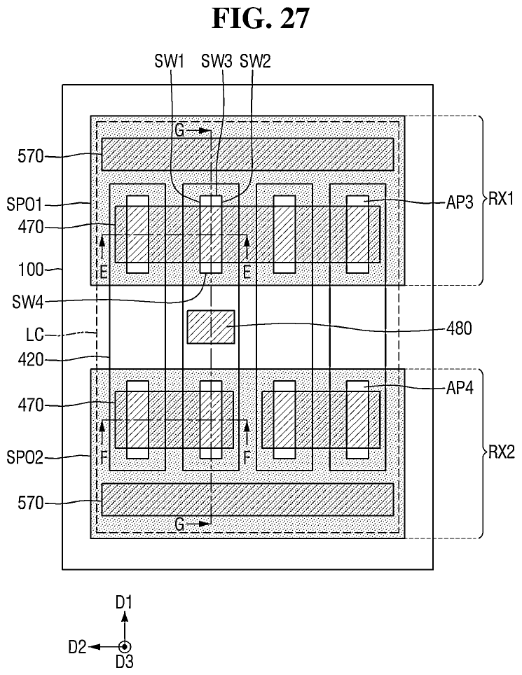

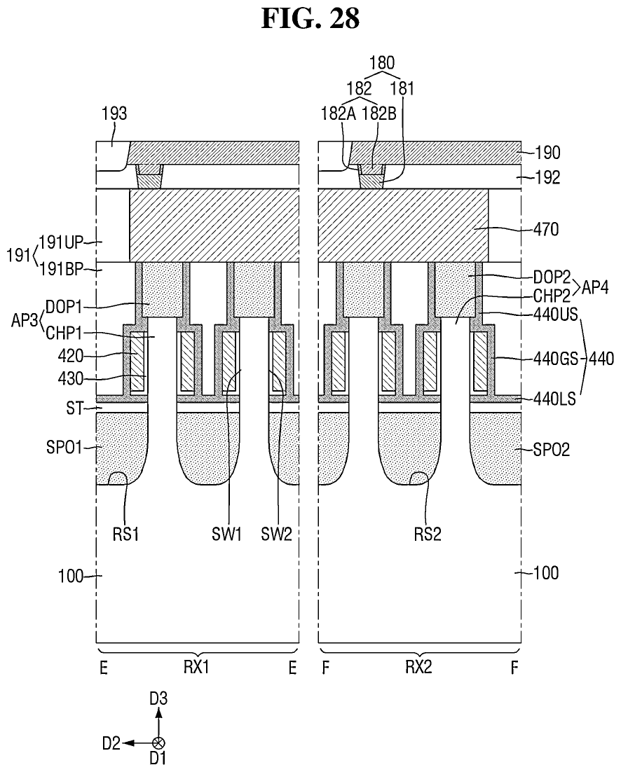

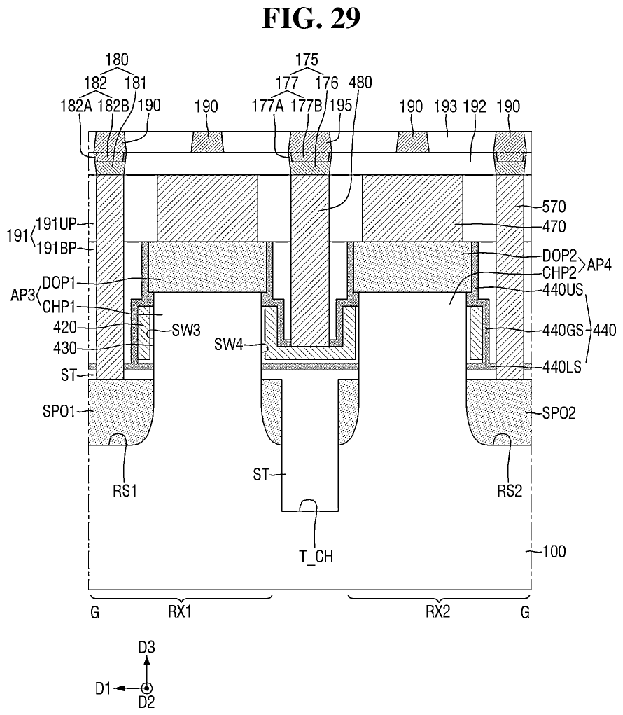

FIGS. 27 to 29 are diagrams for explaining a semiconductor device according to some embodiments. For reference, FIG. 27 is a plan view for explaining the semiconductor device according to some embodiments. FIG. 28 is a cross-sectional view taken along lines E-E and F-F of FIG. 27. FIG. 29 is a cross-sectional view taken along line G-G of FIG. 27.

Referring to FIGS. 27 to 29, a logic cell LC may be provided on the substrate 100. The logic cell LC may refer to a logic element (e.g., an inverter, a flip-flop, or the like) that performs a specific function. The logic cell LC may include vertical transistors (Vertical FET) that constitute a logic element, and wirings that connect the vertical transistors to each other.

The logic cell LC on the substrate 100 may include a first active region RX1 and a second active region RX2. For example, the first active region RX1 may be a PMOSFET region, and the second active region RX2 may be an NMOSFET region. The first and second active regions RX1 and RX2 may be defined by a trench T_CH formed on the top of the substrate 100. The first and second active regions RX1 and RX2 may be spaced apart from each other in the first direction D1.

A first lower epitaxial pattern SPO1 may be provided on the first active region RX1, and a second lower epitaxial pattern SPO2 may be provided on the second active region RX2. From a planar viewpoint, the first lower epitaxial pattern SPO1 may overlap the first active region RX1, and the second lower epitaxial pattern SPO2 may overlap the second active region RX2. The first and second lower epitaxial patterns SPO1 and SPO2 may be epitaxial patterns formed by a selective epitaxial growth process. The first lower epitaxial pattern SPO1 may be provided in the first recess region RS1 of the substrate 100, and the second lower epitaxial pattern SPO2 may be provided in the second recess region RS2 of the substrate 100.

Third active patterns AP3 may be provided on the first active region RX1, and fourth active patterns AP4 may be provided on the second active region RX2. Each of the third and fourth active patterns AP3 and AP4 may have a vertically protruding fin shape. From a planar viewpoint, each of the third and fourth active patterns AP3 and AP4 may have a bar shape extending in the first direction D1. The third active patterns AP3 may be arranged along the second direction D2, and the fourth active patterns AP4 may be arranged along the second direction D2.

Each third active pattern AP3 may include a first channel pattern CHP1 vertically protruding from the first lower epitaxial pattern SPO1, and a first upper epitaxial pattern DOP1 on the first channel pattern CHP1. Each fourth active pattern AP4 may include a second channel pattern CHP2 vertically protruding from the second lower epitaxial pattern SPO2, and a second upper epitaxial pattern DOP2 on the second channel pattern CHP2.

An element separation film ST may be provided on the substrate 100 to fill the trench T_CH. The element separation film ST may cover upper faces of the first and second lower epitaxial patterns SPO1 and SPO2. The third and fourth active patterns AP3 and AP4 may protrude perpendicularly above the element separation film ST.

A plurality of second gate electrodes 420 extending parallel to each other in the first direction D1 may be provided on the element separation film ST. The second gate electrodes 420 may be arranged along the second direction D2. The second gate electrode 420 may surround the first channel pattern CHP1 of the third active pattern AP3, and may surround the second channel pattern CHP2 of the fourth active pattern AP4. For example, the first channel pattern CHP1 of the third active pattern AP3 may have first to fourth side walls SW1 to SW4. The first and second side walls SW1 and SW2 may be opposite to each other in the second direction D2, and the third and fourth side walls SW3 and SW4 may be opposite to each other in the first direction D1. The second gate electrode 420 may be provided on the first to fourth side walls SW1 to SW4. In other words, the second gate electrode 420 may surround the first to fourth side walls SW1 to SW4.

A second gate insulating film 430 may be interposed between the second gate electrode 420 and each of the first and second channel patterns CHP1 and CHP2. The second gate insulating film 430 may cover a bottom face of the second gate electrode 420 and an inner wall of the second gate electrode 420. For example, the second gate insulating film 430 may directly cover the first to fourth side walls SW1 to SW4 of the third active pattern AP3.

The first and second upper epitaxial patterns DOP1 and DOP2 may protrude vertically above the second gate electrode 420. The upper face of the second gate electrode 420 may be lower than the bottom faces of each of the first and second upper epitaxial patterns DOP1 and DOP2. In other words, each of the first and second active patterns AP1 and AP2 may have a structure that vertically protrudes from the substrate 10 and penetrates the second gate electrode 420.

The semiconductor device according to some embodiments may include vertical transistors in which carriers move in the third direction D3. For example, when a voltage is applied to the second gate electrode 420 and the transistor is turned “on”, carriers may move from the lower epitaxial patterns SPO1 and SPO2 to the upper epitaxial patterns DOP1 and DOP2 through the channel patterns CHP1 and CHP2. In the semiconductor device according to some embodiments, the second gate electrode 420 may completely surround the side walls SW1 to SW4 of the channel patterns CHP1 and CHP2. A transistor according to the present disclosure may be a three-dimensional field effect transistor (e.g., VFET) having a gate all-around structure. Since the gate surrounds the channel, the semiconductor device according to the disclosure may have excellent electrical properties.

A spacer 440 that covers the second gate electrodes 420, the third active pattern AP3, and the fourth active patterns AP4 may be provided on the element separation film ST. The spacer 440 may include a silicon nitride film or a silicon oxynitride film. The spacer 440 may include a lower spacer 440LS, an upper spacer 440US, and a second gate spacer 440GS between the lower and upper spacers 440LS and 440US.

The lower spacer 440LS may directly cover the upper surface of the element separation film ST. The second gate electrodes 420 may be spaced apart from the element separation film ST in the third direction D3 by the lower spacer 440LS. The second gate spacer 440GS may cover the upper faces and outer walls of each of the second gate electrodes 420. The upper spacer 440 may cover the first and second upper epitaxial patterns DOP1 and DOP2. However, the upper spacer 440US may not cover the upper faces of the first and second upper epitaxial patterns DOP1 and DOP2, but may expose the upper faces of the first and second upper epitaxial patterns DOP1 and DOP2.

A first portion 191BP of the lower interlayer insulating film may be provided on the spacer 440. An upper face of the first portion 191BP of the lower interlayer insulating film may be substantially coplanar with the upper faces of the first and second upper epitaxial patterns DOP1 and DOP2. A second portion 191UP of the lower interlayer insulating film and the first and second upper interlayer insulating films 192 and 193 may be sequentially stacked on the first portion 191BP of the lower interlayer insulating film. The first portion 191BP of the lower interlayer insulating film and the second portion 191UP of the lower interlayer insulating film may be included in the lower interlayer insulating film 191. The second portion 191UP of the lower interlayer insulating film may cover the upper faces of the first and second upper epitaxial patterns DOP1 and DOP2.

At least one third source/drain contact 470 which penetrates the second portion 191UP of the lower interlayer insulating film and is connected to the first and second upper epitaxial patterns DOP1 and DOP2 may be provided. At least one fourth source/drain contact 570 which sequentially penetrates the lower interlayer insulating film 191, the lower spacer 440LS, and the element separation film ST, and is connected to the first and second lower epitaxial patterns SPO1 and SPO2 may be provided. A second lower gate contact 480 which sequentially penetrates the second portion 191UP of the lower interlayer insulating film, the first portion 191BP of the lower interlayer insulating film, and the second gate spacer 440GS and is connected to the second gate electrode 420 may be provided.

Although it is not shown, an etching stop film 155 may be additionally disposed between the second portion 191UP of the lower interlayer insulating film and the first upper interlayer insulating film 192.

The source/drain via pattern 180, the first gate contact 175, the first wiring line 190, and the second wiring line 195 may be provided on the third source/drain contact 470, the fourth source/drain contact 570, and the second lower gate contact 480. The source/drain via pattern 180 may be connected to the third source/drain contact 470 and the fourth source/drain contact 570. The first gate contact 175 may be connected to the second lower gate contact 480.

The detailed description of the source/drain via pattern 180, the first gate contact 175, the first wiring line 190, and the second wiring line 195 may be substantially the same as that described above with reference to FIGS. 1 to 22.

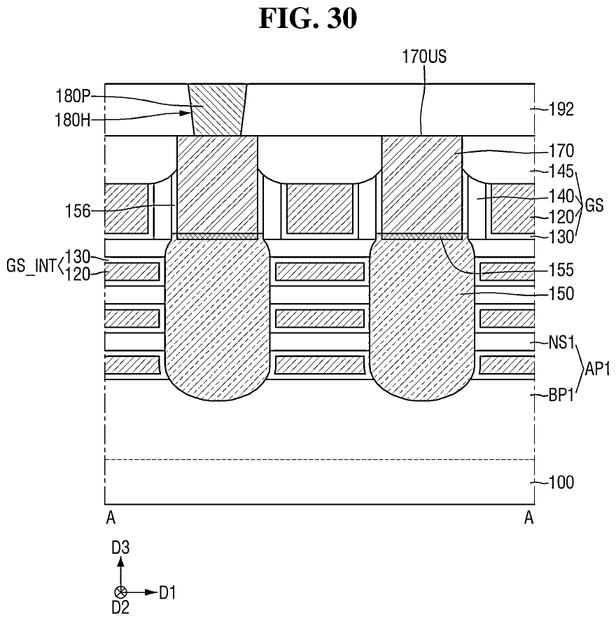

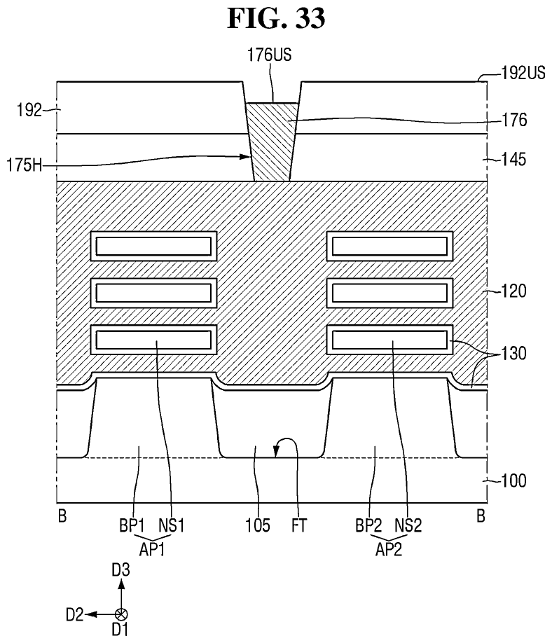

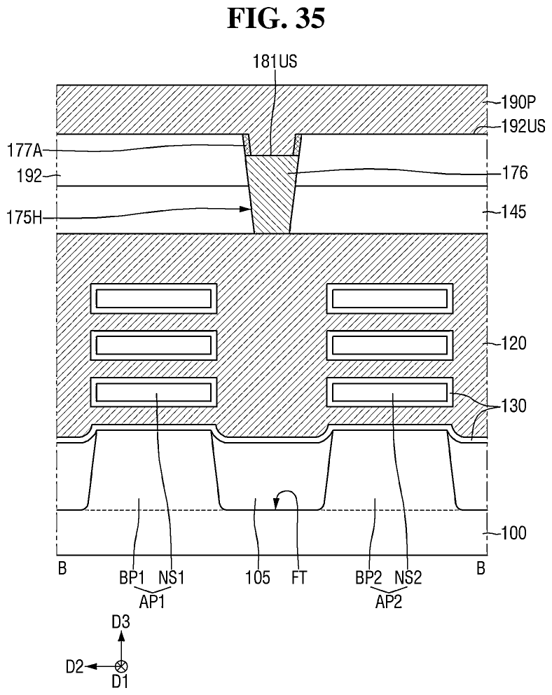

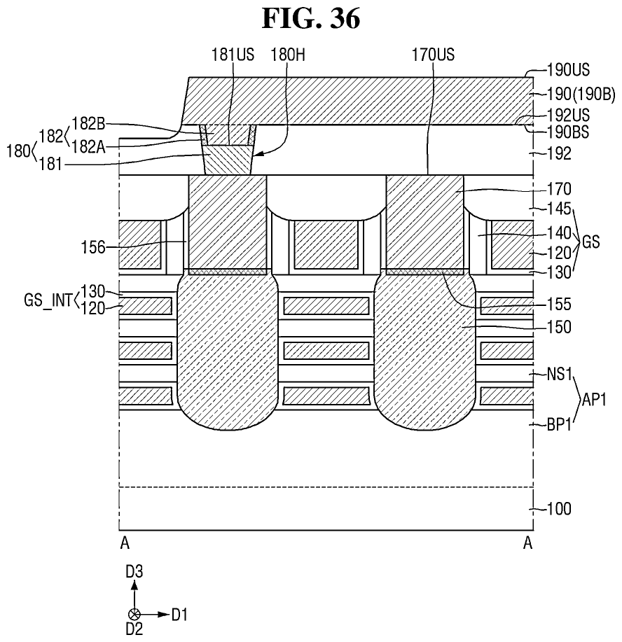

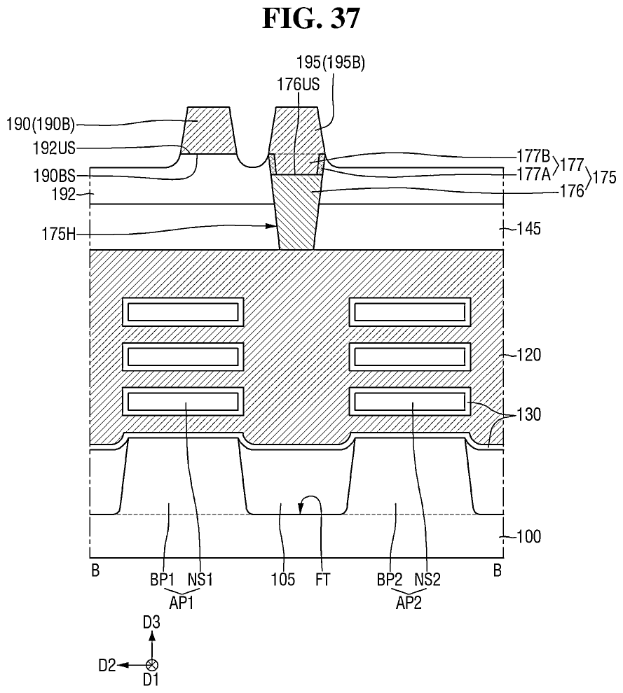

FIGS. 30 to 37 are intermediate stage diagrams for explaining a method for fabricating a semiconductor device according to some embodiments.

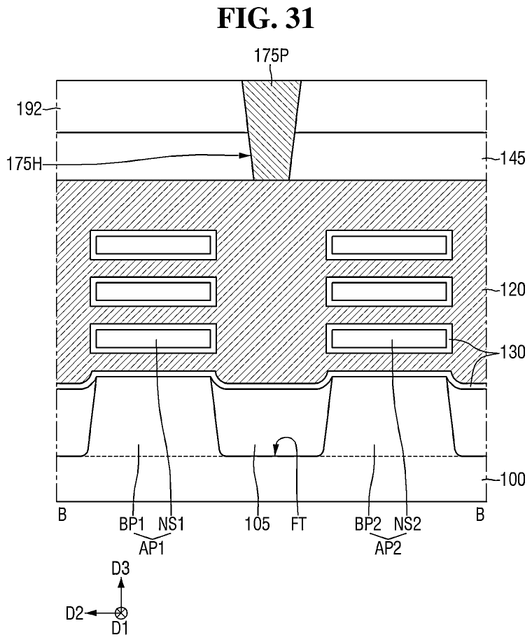

Referring to FIGS. 30 and 31, a first source/drain pattern 150 is formed on the first lower pattern BP1.

Although it is not shown, a source/drain pattern may be formed on the second lower pattern BP2. Before forming the first source/drain pattern 150, the first gate spacer 140 may be formed on the first lower pattern BP1 and the second lower pattern BP2.

A first gate insulating film 130 and a first gate electrode 120 that surround the first sheet pattern NS1 and the second sheet pattern NS2 may be formed on the first lower pattern BP1 and the second lower pattern BP2. The gate capping pattern 145 may be formed on the first gate electrode 120. The gate structure GS may be formed on the first active pattern AP1 and the second active pattern AP2, accordingly.

The first source/drain contact 170 may then be formed on the first source/drain pattern 150. The first source/drain contact 170 is electrically connected to the first source/drain pattern 150.

Subsequently, the first upper interlayer insulating film 192 may be formed on the first source/drain contact 170 and the gate capping pattern 145.

A source/drain via hole 180H may be formed in the first upper interlayer insulating film 192. The source/drain via hole 180H exposes the first source/drain contact 170. A pre-source/drain via pattern 180P is formed in the source/drain via hole 180H. The pre-source/drain via pattern 180P is connected to the first source/drain contact 170.

The gate contact hole 175H may be formed in the first upper interlayer insulating film 192 and the gate capping pattern 145. The gate contact hole 175H exposes the first gate electrode 120. A pre-gate contact 175P is formed in the gate contact hole 175H. The pre-gate contact 175P is connected to first gate electrode 120.

As an example, after forming the pre-source/drain via pattern 180P, the pre-gate contact 175P may be formed. As another example, the pre-gate contact 175P may be formed before the pre-source/drain via pattern 180P is formed. As yet another example, the pre-source/drain via pattern 180P and the pre-gate contact 175P may be formed simultaneously.

Referring to FIGS. 30 to 33, a lower via pattern 181 may be formed by removing a part of the pre-source/drain via pattern 180P.

The upper face 181US of the lower via pattern becomes lower than the upper face 192US of the first upper interlayer insulating film, accordingly.

A part of the pre-gate contact 175P may be removed to form a lower gate contact 176. The upper face 176US of the lower gate contact becomes lower than the upper face 192US of the first upper interlayer insulating film, accordingly.

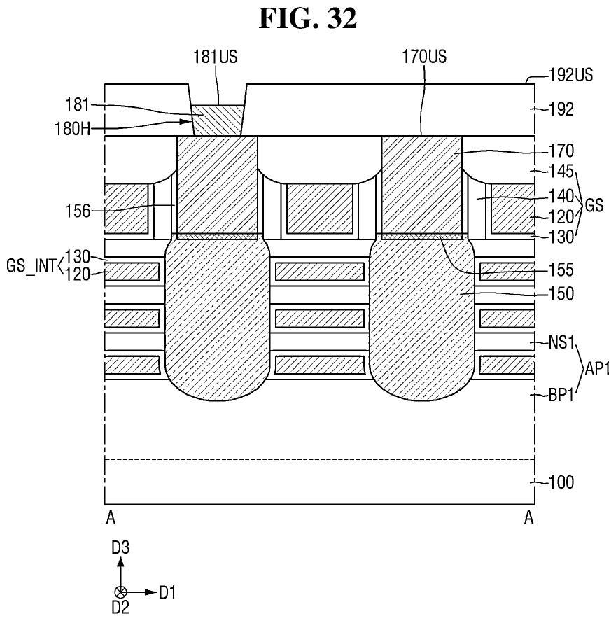

Referring to FIGS. 32 to 35, the upper via barrier film 182A may be formed along a part of the side wall of the source/drain via hole 180H.

The upper gate barrier film 177A may be formed along a part of the side wall of the gate contact hole 175H. The upper gate barrier film 177A and the upper via barrier film 182A may be formed at the same time.

Unlike the shown example, as an example, each of the upper gate barrier film 177A and the upper via barrier film 182A may extend along the upper face 192US of the first upper interlayer insulating film. As another example, the upper gate barrier film 177A may extend along the upper face 176US of the lower gate contact. The upper via barrier film 182A may extend along the upper face 181US of the lower via pattern.

Subsequently, a wiring conductive film 190P may be formed on the first upper interlayer insulating film 192. The wiring conductive film 190P may cover the upper face 192US of the first upper interlayer insulating film. The wiring conductive film 190P may fill the source/drain via hole 180H that remains after the lower via pattern 181 is formed. The wiring conductive film 190P may fill the gate contact hole 175H that remains after the lower gate contact 176 is formed. The wiring conductive film 190P contains ruthenium (Ru).

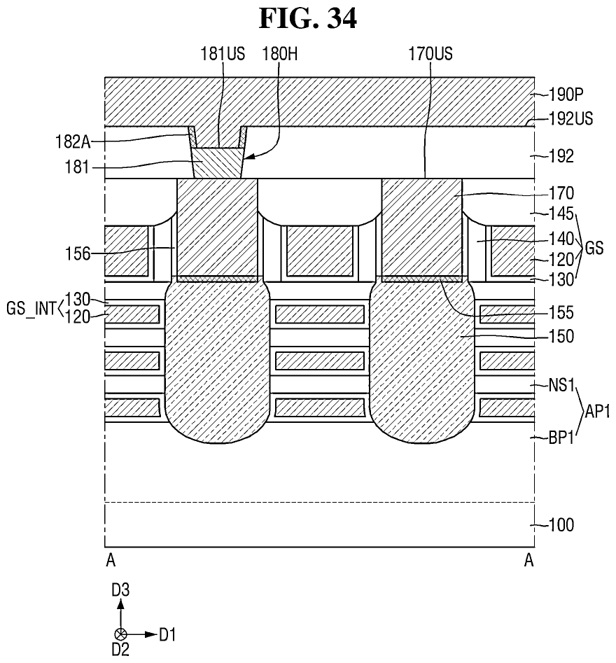

Referring to FIGS. 34 to 37, the first wiring layer 190 and the second wiring 195 may be formed on the first upper interlayer insulating film 192 by patterning the wiring conductive film 190P.

While the first wiring line 190 is being formed, the upper via filling film 182B may be formed in the source/drain via hole 180H. The upper via pattern 182 may be formed in the source/drain via hole 180H, accordingly.

While the second wiring line 195 is being formed, an upper gate filling film 177B may be formed in the gate contact hole 175H. The upper gate contact 177 may be formed in the gate contact hole 175H, accordingly.

For example, ruthenium (Ru) may be etched, using a gas containing oxygen. In other words, the first wiring line 190 and the second wiring line 195 may be etched in an environment that includes oxygen. The lower via pattern 181 and/or the lower gate contact 176 may include molybdenum (Mo). When the lower via pattern 181 and/or the lower gate contact 176 are exposed during the formation of the first wiring line 190 and the second wiring line 195, the lower via pattern 181 and/or the lower gate contact 176 may be easily oxidized. When molybdenum is oxidized, the reliability and performance of the semiconductor device may be degraded. On the other hand, when a part of the lower via pattern 181 and the lower gate contact 176 are removed before formation of the wiring conductive film 190P, during formation of the first wiring line 190 and the second wiring line 195, the lower via pattern 181 and the lower gate contact 176 may be limited and/or prevented from being exposed.

While the first wiring line 190 and the second wiring line 195 are being formed, the upper gate filling film 177B and/or the upper via filling film 182B may be over-etched as shown in FIGS. 10 to 12.

A misalignment may occur between the first wiring line 190 and the source/drain via pattern 180. The misalignment may occur between the second wiring line 195 and the first gate contact 175. Even if the misalignment occurs, the over-etching of the upper gate filling film 177B and the upper via filling film 182B may progress. Accordingly, a sufficient space margin between the first wiring line 190 and the first gate contact 175 may be ensured. Further, a sufficient space margin between the second wiring line 195 and the source/drain via pattern 180 may be ensured.

Subsequently, the second upper interlayer insulating film 193 may be formed on the first wiring line 190 and the second wiring line 195.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor device comprising:
a conductive pattern on a substrate;
a via pattern connected to the conductive pattern, the via pattern including a lower via pattern and an upper via pattern, the lower via pattern and the upper via pattern being stacked in a first direction, an upper face of the lower via pattern being in contact with a bottom face of the upper via pattern; and
a wiring line on the via pattern and extending in a second direction, wherein
a metal in the wiring line is the same as a metal in the upper via pattern,
a bottom face of the wiring line and an upper face of the wiring layer are opposite each other in the first direction,
the bottom face of the wiring line is connected to the upper via pattern,
a width of the bottom face of the wiring line in a third direction is greater than a width of the upper face of the wiring line in the third direction,
a width of an upper face of the lower via pattern in the second direction is equal to a width of a bottom face of the upper via pattern in the second direction, and
a width of the upper face of the lower via pattern in the third direction is equal to a width of the bottom face of the upper via pattern in the third direction.

2. The semiconductor device of claim 1, wherein
the upper via pattern and the lower via pattern each include a first side wall and a second side wall opposing each other in the third direction,
a sign of a slope of the first side wall of the lower via pattern is the same as a sign of a slope of the second side wall of the lower via pattern,
a sign of a slope of the first side wall of the upper via pattern is the same as a sign of a slope of the second side wall of the upper via pattern, and
the sign of the slope of the first side wall of the lower via pattern is different from the sign of the slope of the first side wall of the upper via pattern.

3. The semiconductor device of claim 2,
wherein the upper via pattern includes a third side wall and a fourth side wall opposing each other in the second direction,
a sign of a slope of the third side wall of the upper via pattern is the same as a sign of a slope of the fourth side wall of the upper via pattern, and
the sign of the slope of the first side wall of the lower via pattern is the same as the sign of the slope of the third side wall of the upper via pattern.

4. The semiconductor device of claim 1, wherein
the upper via pattern and the lower via pattern each include a first side wall and a second side wall opposing each other in the third direction,
a sign of a slope of the first side wall of the lower via pattern is the same as a sign of a slope of the second side wall of the lower via pattern,
a sign of a slope of the first side wall of the upper via pattern is the same as a sign of a slope of the second side wall of the upper via pattern, and
the sign of the slope of the first side wall of the lower via pattern is the same as the sign of the slope of the first side wall of the upper via pattern.

5. The semiconductor device of claim 1, wherein
the upper via pattern includes a first side wall and a second side wall opposing each other in the third direction,
a sign of a slope of the first side wall of the upper via pattern is different from a sign of a slope of the second side wall of the upper via pattern.

6. The semiconductor device of claim 1, wherein
the upper via pattern includes an upper via filling film and an upper via barrier film,
the upper via filling film is in contact with an upper face of the lower via pattern, the upper via barrier film extends along a side wall of the upper via filling film,
the wiring line is a single metal conductive film, and
a metal included in the wiring line is the same as the a metal included in the upper via filling film.

7. The semiconductor device of claim 1, wherein
the upper via pattern includes an upper via filling film and an upper via barrier film, the upper via barrier extends along a side wall of the upper via filling film,
the wiring line includes a wiring extension line and a wiring barrier film extending along a bottom face of the wiring extension line,
the wiring barrier film and the upper via barrier film include a same conductive material, and
a metal included in the wiring extension line is the same as a metal included in the upper via filling film.

8. The semiconductor device of claim 7, wherein
the upper via filling film is in contact with an upper face of the lower via pattern.

9. The semiconductor device of claim 7, wherein
the upper via barrier film extends along a bottom face of the upper via filling film.

10. The semiconductor device of claim 1,
wherein the lower via pattern includes molybdenum (Mo), and
the upper via pattern includes ruthenium (Ru).

11. The semiconductor device of claim 1, further comprising:
a gate electrode and a source/drain pattern on the substrate; and
a source/drain contact connected to the source/drain pattern, wherein
the conductive pattern is one of the gate electrode and the source/drain contact.

12. A semiconductor device comprising:
a conductive pattern on a substrate;
an interlayer insulating film on the conductive pattern and including a via hole;
a lower via pattern connected to the conductive pattern and filling a part of the via hole; and
a wiring line pattern filling a remainder of the via hole, wherein
the wiring line pattern is in contact with an upper face of the interlayer insulating film,
the wiring line pattern includes an upper via pattern and a wiring extension line,
the wiring line pattern is in the via hole and in contact with an entire upper face of the lower via pattern,
the wiring extension line extends in a first direction along the upper face of the interlayer insulating film,
the upper via pattern includes an upper via filling film and an upper via barrier film extending along a side wall of the upper via filling film,
the wiring extension line and the upper via filling film have an integral structure, and
a width of the wiring extension line in the second direction decreases as the wiring extension line goes away from the lower via pattern.

13. The semiconductor device of claim 12,
wherein the wiring extension line is in contact with the upper face of the interlayer insulating film.

14. The semiconductor device of claim 12,
wherein the upper via barrier film extends along an upper face of the lower via pattern, and
the lower via pattern and the upper via filling film are separated by the upper via barrier film.

15. The semiconductor device of claim 12,
wherein the wiring line pattern further comprises a wiring barrier film,
the wiring barrier film extends along a bottom face of the wiring extension line and is in contact with the upper face of the interlayer insulating film, and
the wiring barrier film is directly connected to the upper via barrier film, and
the wiring barrier film includes a same conductive material as the upper via barrier film.

16. The semiconductor device of claim 12,
wherein the upper via filling film is directly connected to the lower via pattern.

17. A semiconductor device comprising:
a gate electrode on a substrate;
a source/drain pattern on a side of the gate electrode;
a source/drain contact on the source/drain pattern and connected to the source/drain pattern;
a via pattern connected to the source/drain contact,
the via pattern including a lower via pattern and an upper via pattern, which are stacked in a first direction, and
an entire upper face of the lower via pattern being in contact with the upper via pattern;
a gate contact connected to the gate electrode,
the gate contact including a lower gate contact and an upper gate contact, which are stacked in the first direction, and
an entire upper face of the lower gate contact being in contact with the upper gate contact;
a first wiring extension line on the via pattern and extending in a second direction; and
a second wiring extension line on the gate contact, wherein
the upper via pattern includes an upper via filling film and an upper via barrier film,
the upper via filling is directly connected to the first wiring extension line, and
the upper via barrier film extends along a side wall of the upper via filling film,
the upper gate contact includes an upper gate contact filling film and an upper gate contact barrier film,
the upper gate contact film is directly connected to the second wiring extension line,
the upper gate contact barrier film extends along a side wall of the upper gate contact filling film,
a width of the first wiring extension line in a third direction decreases as the first wiring extension line goes away from the source/drain contact,
a width of the second wiring extension line in the third direction decreases as the second wiring extension line goes away from the gate electrode, and
the first wiring extension line, the second wiring extension line, the upper via filling film, and the upper gate contact filling film each include ruthenium (Ru).

18. The semiconductor device of claim 17, wherein
the upper via filling film is directly connected to the lower via pattern, and
the upper gate contact filling film is directly connected to the lower gate contact.

19. The semiconductor device of claim 17, wherein
the lower via pattern and the lower gate contact include molybdenum (Mo).

20. The semiconductor device of claim 17, comprising:
a plurality of sheet patterns on the substrate, wherein
the gate electrode surrounds a sheet pattern among the plurality of sheet patterns.
